(19) United States
(12) Patent Application Publication
(10) Pub. No.: US 2023/0422488 A1
(43) Pub. Date: Dec. 28, 2023

(54) SEMICONDUCTOR DEVICES

(71) Applicant: Samsung Electronics Co., Ltd., Suwon-si (KR)

(72) Inventors: Jongmin KIM, Suwon-si (KR); Sohyun Park, Suwon-si (KR); Chansic Yoon, Suwon-si (KR); Dongmin Choi, Suwon-si (KR); Seungbo Ko, Suwon-si (KR); Hyosub Kim, Suwon-si (KR); Jingkuk Bae, Suwon-si (KR); Woojin Jeong, Suwon-si (KR); Eunkyung Cha, Suwon-si (KR); Junhyeok Ahn, Suwon-si (KR)

(73) Assignee: Samsung Electronics Co., Ltd., Suwon-si (KR)

(21) Appl. No.: 18/192,329

(22) Filed: Mar. 29, 2023

(30) Foreign Application Priority Data
Jun. 24, 2022 (KR) 10-2022-0077280

(51) Int. Cl. H10B 12/00

(52) U.S. Cl. CPC H10B 12/485; H10B 12/0335; H10B 12/482; H10B 12/315

(57) ABSTRACT

A semiconductor device including a first contact plug structure on a substrate, a lower spacer structure on a sidewall of the first contact plug structure, and a bit line structure on the first contact plug structure and including a conductive structure and an insulation structure stacked in a vertical direction substantially perpendicular to an upper surface of the substrate may be provided. The first contact plug structure may include a conductive pad contacting the upper surface of the substrate, an ohmic contact pattern on the conductive pad, and a conductive filling pattern on the ohmic contact pattern. The conductive filling pattern may include metal, and include a lower portion having a relatively large width and an upper portion having a relatively small width. The lower spacer structure may contact a sidewall of the conductive filling pattern.

### CROSS-REFERENCE TO RELATED APPLICATION

This application claims priority under 35 U.S.C. § 119 to Korean Patent Application No. 10-2022-0077280 filed on Jun. 24, 2022 in the Korean Intellectual Property Office, the disclosure of which is hereby incorporated by reference in its entirety.

### BACKGROUND

### Technical Field

Example embodiments of the present disclosure relate to semiconductor devices. More particularly, example embodiments of the present disclosure relate to DRAM devices.

### Discussion of Related Art

In a DRAM device, a conductive contact plug may be formed under a bit line structure to contact an active pattern, and the conductive contact plug and conductive structures adjacent thereto may be electrically shorted due to misalignment during a manufacturing process of the DRAM device

### SUMMARY

Some example embodiments provide semiconductor devices having improved characteristics.

According to an example embodiment of the inventive concepts, a semiconductor device may include a first contact plug structure on a substrate, a lower spacer structure on a sidewall of the first contact plug structure, and a bit line structure on the first contact plug structure and including a conductive structure and an insulation structure stacked in a vertical direction substantially perpendicular to an upper surface of the substrate. The first contact plug structure may include a conductive pad contacting the upper surface of the substrate, an ohmic contact pattern on the conductive pad, and a conductive filling pattern on the ohmic contact pattern. The conductive filling pattern may include metal, and include a lower portion having a relatively large width and an upper portion having a relatively small width. The lower spacer structure may contact a sidewall of the conductive filling pattern.

According to an example embodiment of the inventive concepts, a semiconductor device may include a contact plug structure on a substrate, a lower spacer structure on a sidewall of the contact plug structure, and a bit line structure on the contact plug structure and including a conductive structure and an insulation structure stacked in a vertical direction substantially perpendicular to an upper surface of the substrate. The contact plug structure may include an ohmic contact pattern contacting the upper surface of the substrate and a conductive filling pattern on the ohmic contact pattern. The conductive filling pattern may include metal, and include a lower portion having a relatively large width and an upper portion having a relatively small width. The ohmic contact pattern may cover at least a portion of a sidewall of the lower portion of the conductive filling pattern.

According to an example embodiment of the inventive concepts, a semiconductor device may include an active pattern on a substrate, a contact plug structure on the active pattern and including a conductive pad on an upper surface of the active pattern, an ohmic contact pattern on the conductive pad, and a conductive filling pattern on the ohmic contact pattern, a lower spacer structure on a sidewall of the conductive pad, a capping pattern on sidewalls of the ohmic contact pattern and the conductive filling pattern and an upper surface of the lower spacer structure, an insulating filling pattern on the capping pattern, and a bit line structure on the contact plug structure and including a conductive structure and an insulation structure stacked in a vertical direction substantially perpendicular to an upper surface of the substrate.

In some semiconductor devices in accordance with some example embodiments, the contact plug structure between the active pattern and the bit line structure may have a reduced resistance.

### BRIEF DESCRIPTION OF THE DRAWINGS

FIG. 1 is a plan view illustrating a semiconductor device in accordance with an example embodiment, FIG. 2A is a cross-sectional view taken along line A-A′ of FIG. 1, and FIG. 2B is an enlarged cross-sectional view of region X in FIG. 2A.

FIGS. 3 to 24 are plan views and cross-sectional views illustrating a method of manufacturing a semiconductor device in accordance with an example embodiment.

FIGS. 25A and 25B are cross-sectional views illustrating a semiconductor device in accordance with an example embodiment.

FIGS. 26 and 27 are cross-sectional views illustrating a method of manufacturing a semiconductor device of FIGS. 25A and 25B in accordance with an example embodiment.

FIGS. 28A and 28B are cross-sectional views illustrating semiconductor devices in accordance with an example embodiment.

FIGS. 29 to 31 are cross-sectional views illustrating a method of manufacturing a semiconductor device of FIGS. 28A and 28B in accordance with an example embodiment.

FIG. 32 is a cross-sectional view illustrating a semiconductor device in accordance with an example embodiment.

FIGS. 33 to 37 are cross-sectional views illustrating a method of manufacturing a semiconductor device of FIG. 32 in accordance with an example embodiment.

FIGS. 38 to 40 are cross-sectional views illustrating semiconductor devices, respectively, in accordance with some example embodiments.

### DETAILED DESCRIPTION

The above and other aspects and features of semiconductor devices and methods of forming the same in accordance with some example embodiments will become readily understood from detail descriptions that follow, with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of inventive concepts.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

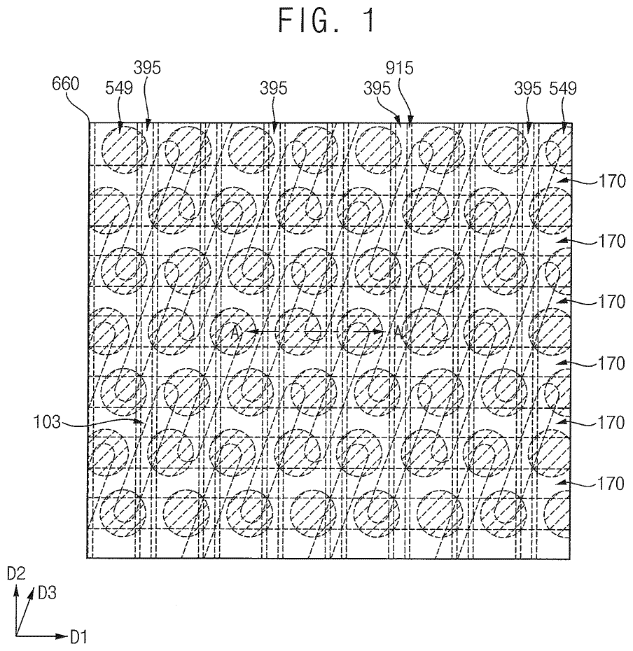

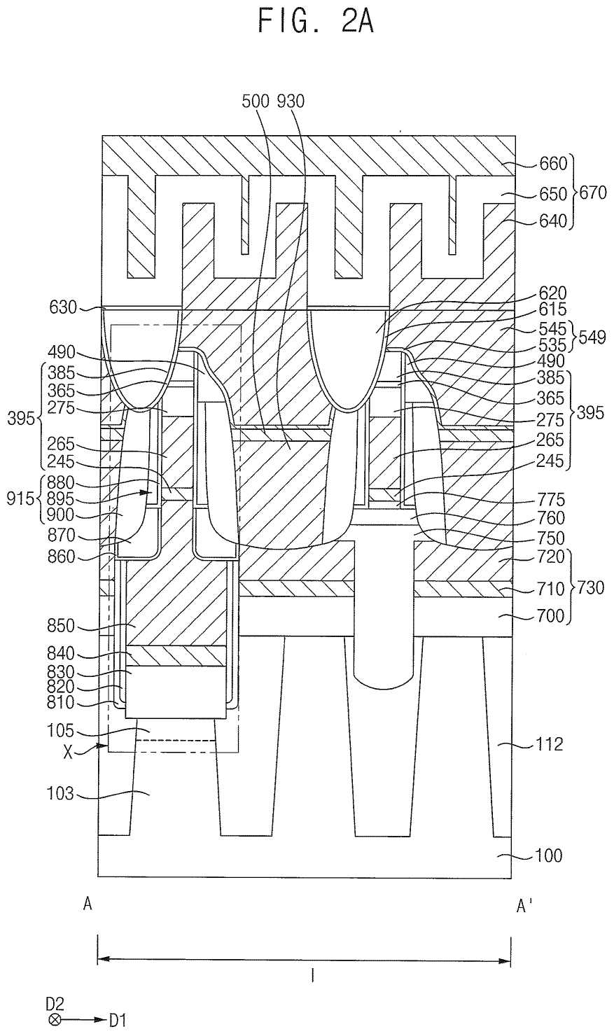

FIG. 1 is a plan view illustrating a semiconductor device in accordance with example embodiments, FIG. 2A is a cross-sectional view taken along line A-A′ of FIG. 1, and FIG. 2B is an enlarged cross-sectional view of region X in FIG. 2A.

Hereinafter, in the specification (and not necessarily in the claims), two directions that are substantially perpendicular to each other among horizontal directions, which are substantially parallel to an upper surface of a substrate 100, may be referred to as first and second directions D1 and D2, respectively, and a direction having an acute angle with respect to the first and second directions D1 and D2 among the horizontal directions may be referred to as a third direction D3.

Referring to FIGS. 1, 2A and 2B, the semiconductor device may include an active pattern 103, a gate structure 170, a filling structure, a bit line structure 395, first and second contact structures, and a capacitor 670.

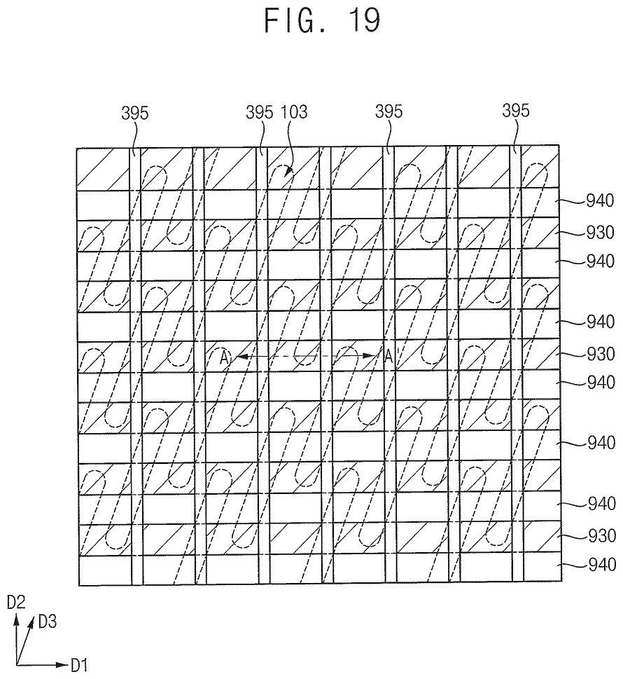

The semiconductor device may further include an isolation pattern 112, a conductive pad structure 730, first and second insulation pad layers 750 and 760, a third insulation pad 775, an upper spacer structure 915, a third capping pattern 940 (refer to FIG. 19), an insulation pattern structure, an etch stop layer 630 and a fourth upper spacer 490.

The substrate 100 may include silicon, germanium, silicon-germanium, or a III-V group compound semiconductor, such as GaP, GaAs, or GaSb. In some example embodiments, the substrate 100 may be a silicon-on-insulator (SOI) substrate or a germanium-on-insulator (GOI) substrate.

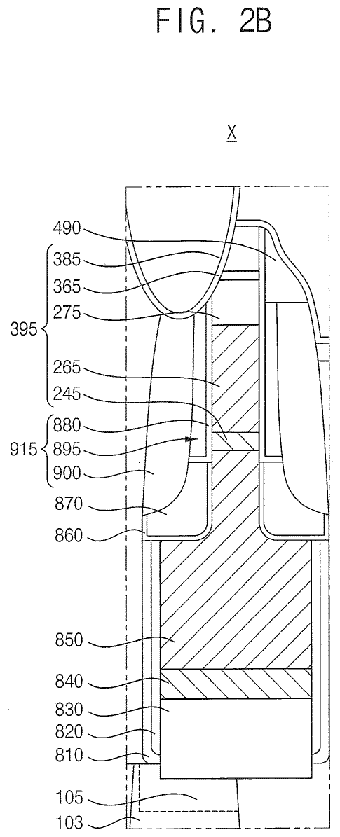

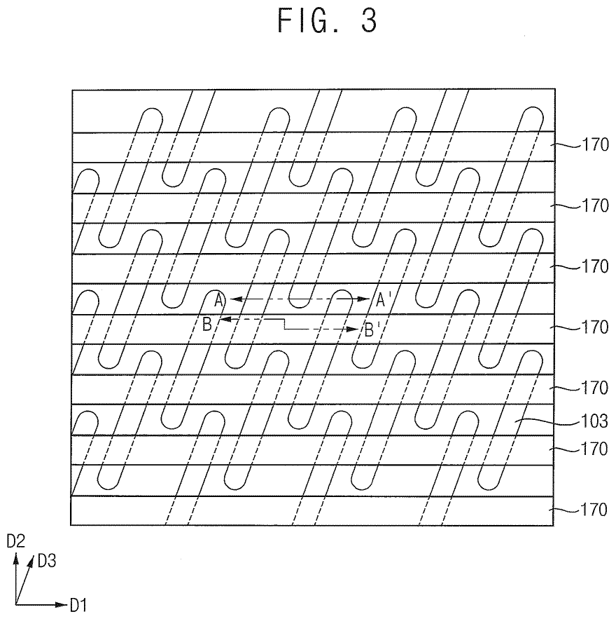

Referring to FIG. 3, the active pattern 103 may extend in the third direction D3, and a plurality of active patterns 103 may be spaced apart from each other in the first and second directions D1 and D2. A sidewall of the active pattern 103 may be covered by the isolation pattern 112. The active pattern 103 may include a material substantially the same as a material of the substrate 100, and the isolation pattern 112 may include oxide (e.g., silicon oxide).

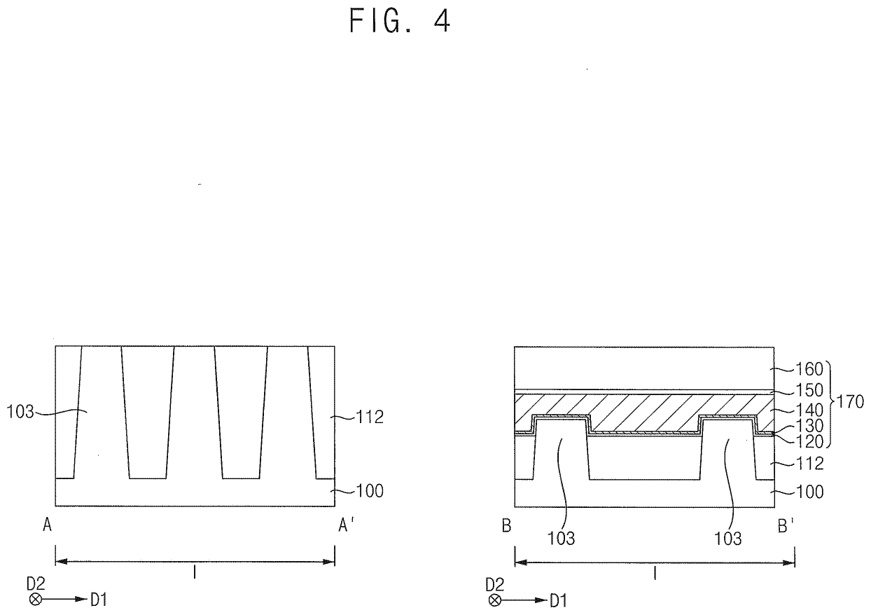

Referring to FIG. 4, the gate structure 170 may be formed in a second recess extending in the first direction D1 through upper portions of the active pattern 103 and the isolation pattern 112. The gate structure 170 may include a gate insulation pattern 120 on a bottom and a sidewall of the second recess, a first barrier pattern 130 on a portion of the gate insulation pattern 120 on the bottom and a lower sidewall of the second recess, a first conductive pattern 140 on the first barrier pattern 130 and filling a lower portion of the second recess, a second conductive pattern 150 on upper surfaces of the first barrier pattern 130 and the first conductive pattern 140, and a gate mask 160 on an upper surface of the second conductive pattern 150 and an upper inner sidewall of the gate insulation pattern 120 and filling an upper portion of the second recess. The first barrier pattern 130, the first conductive pattern 140 and the second conductive pattern 150 may form a gate electrode.

The gate insulation pattern 120 may include oxide (e.g., silicon oxide), the first barrier pattern 130 may include metal nitride (e.g., titanium nitride or tantalum nitride), the first conductive pattern 140 may include, for example, metal, metal nitride, metal silicide, or doped polysilicon, the second conductive pattern 150 may include, for example, doped polysilicon, and the gate mask 160 may include nitride (e.g., silicon nitride).

In some example embodiments, the gate structure 170 may extend in the first direction D1, and a plurality of gate structures 170 may be spaced apart from each other in the second direction D2.

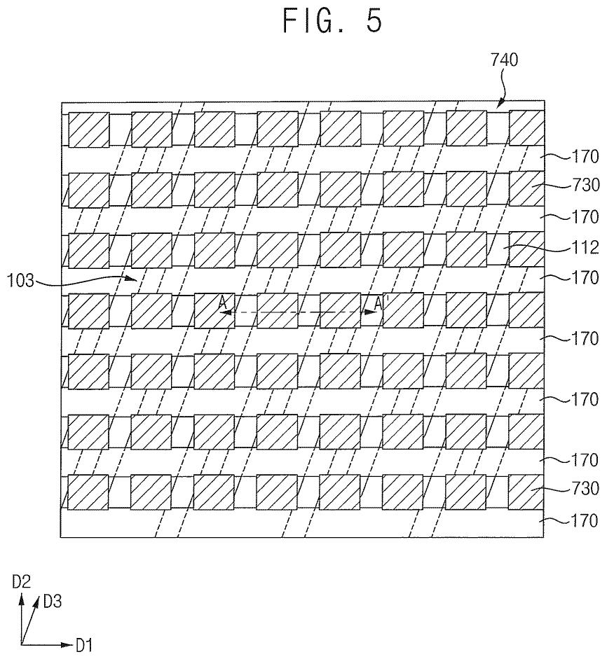

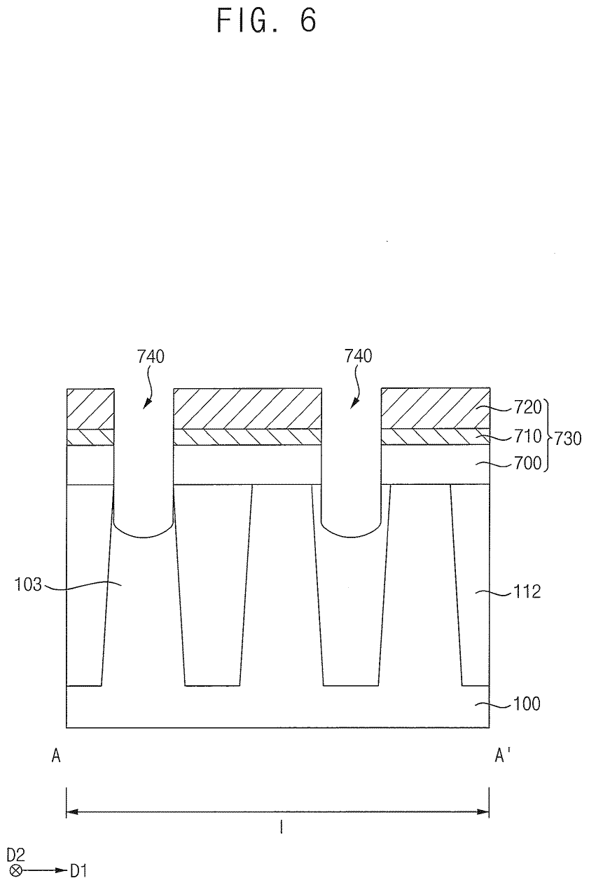

Referring to FIGS. 5 and 6, in some example embodiments, a plurality of conductive pad structures 730 may be spaced apart from each other in the first and second directions D1 and D2, and may be arranged in a lattice pattern in a plan view.

In some example embodiments, the conductive pad structure 730 may overlap in the third direction an end portion of the active pattern 103 extending in the third direction D3 and a portion of the isolation pattern 112 adjacent to the end portion of the active pattern 103 in the first direction D1. Although not apparent from FIG. 2A (e.g., the cross-sectional view taken along line A-A′ of FIG. 1), the conductive pad structure 730 may be in contact with each of opposite edge portions of the active pattern 103.

In some example embodiments, the conductive pad structure 730 may include first, second and third conductive pads 700, 710 and 720 sequentially stacked in the vertical direction. In some example embodiments, the first conductive pad 700 may include doped polysilicon, the second conductive pad 710 may include metal silicide (e.g., titanium silicide, cobalt silicide, or nickel silicide), metal nitride (e.g., titanium nitride, tantalum nitride, or tungsten nitride), or metal silicon nitride (e.g., titanium silicon nitride or tantalum silicon nitride)., and the third conductive pad 720 may include metal, (e.g., tungsten or ruthenium). Thus, the conductive pad structure 730 may have a multi-layered structure.

Referring to FIGS. 5, 6 and 8, in some example embodiments, the first insulation pad layer 750 may be formed in a first opening 740 extending through the conductive pad structure 730 to expose an upper surface of the active pattern 103 or an upper surface of the isolation pattern 112, and the second insulation pad layer 760 and the third insulation pad 775 may be stacked on the first insulation pad layer 750. The first opening 740 may include a first portion extending in the first direction D1 and a second portion extending in the second direction D2 that are connected to each other. Thus, the first insulation pad layer 750 in the first opening 740 may surround the conductive pad structure 730 that may be arranged in a lattice pattern in a plan view.

In some example embodiments, the first insulation pad layer 750 and the third insulation pad 775 may include insulating nitride (e.g., silicon nitride), and the second insulation pad layer 760 may include metal oxide(e.g., hafnium oxide or zirconium oxide).

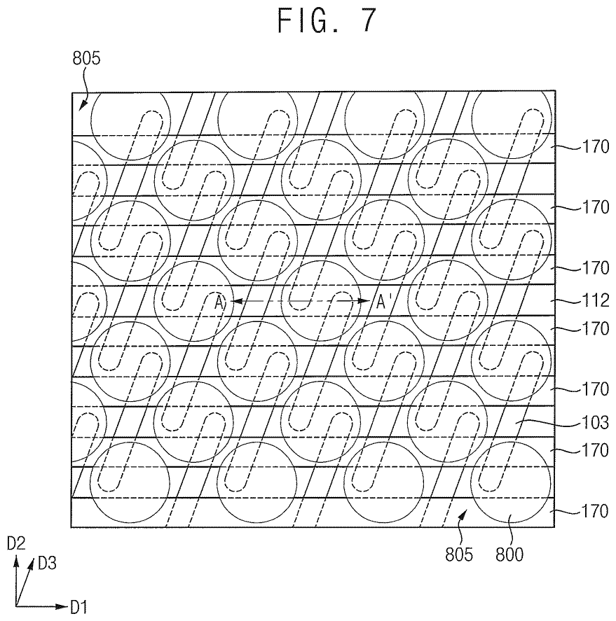

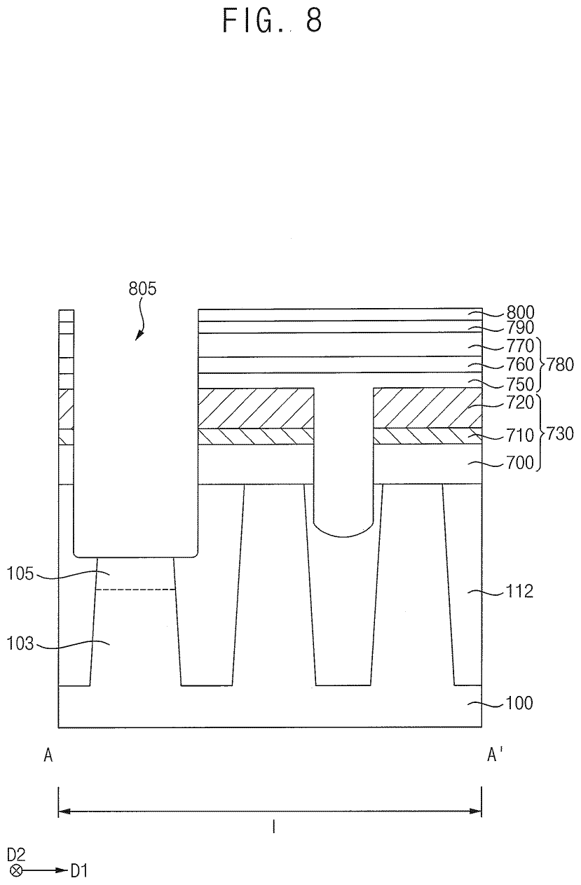

Referring to FIGS. 7 and 8, a second opening 805 may be formed through the conductive pad structure 730 to expose upper surfaces of the active pattern 103, the isolation pattern 112 and the gate mask 160 included in the gate structure 170, and an upper surface of a central portion of the active pattern 103 in the third direction D3 may be exposed by the second opening 805.

In some example embodiments, an area of a lower surface of the second opening 805 may be greater than an area of the upper surface of the active pattern 103 exposed by the second opening 805. Thus, the second opening 805 may also expose an upper surface of a portion of the isolation pattern 112 adjacent to the active pattern 103.

An impurity region 105 including n-type or p-type impurities may be formed in an upper portion of the active pattern 103 exposed by the second opening 805, and the filling structure may be formed in the second opening 805 to contact an upper surface of the impurity region 105.

In some example embodiments, the filling structure may include a first contact plug structure, a lower spacer structure, a second capping pattern 860 and an insulating filling pattern 870.

The first contact plug structure may include a fourth conductive pad 830, a first ohmic contact pattern 840 and a conductive filling pattern 850 sequentially stacked in the vertical direction on the upper surfaces of the impurity region 105 and the isolation pattern 112.

The fourth conductive pad 830 may include single crystalline silicon doped with n-type or p-type impurities or polysilicon doped with n-type or p-type impurities. In an example embodiment, a seam or void may be formed in the fourth conductive pad 830.

In some example embodiments, an area of a lower surface of the fourth conductive pad 830 may be greater than an area of the upper surface of the active pattern or the upper surface of the impurity region 105 exposed by the second opening 805. Additionally, an area of an upper surface of the fourth conductive pad 830 may also be greater than the area of the upper surface of the active pattern or the upper surface of the impurity region 105 exposed by the second opening 805.

The first ohmic contact pattern 840 may include metal silicide (e.g., titanium silicide, cobalt silicide or nickel silicide). The conductive filling pattern 850 may include metal nitride (e.g., titanium nitride, tantalum nitride, or tungsten nitride), and/or metal (e.g., titanium, tantalum, or tungsten).

In some example embodiments, the conductive filling pattern 850 may include a lower portion having a large width and an upper portion having a relatively small width.

In some example embodiments, at least a portion of the first contact plug structure may be formed at a level substantially the same as a level of the conductive pad structure 730, and thus may overlap the conductive pad structure 730 in the horizontal direction.

The lower spacer structure may cover a sidewall of the first contact plug structure, for example, sidewalls of the fourth conductive pad 830, the first ohmic contact pattern 840 and the lower portion of the conductive filling pattern 850, and may include a second lower spacer and a first lower spacer 820 and 810 stacked in the horizontal direction from the sidewall of the first contact plug structure. The first lower spacer 810 may include oxide (e.g., silicon oxide), and the second lower spacer 820 may include, for example, silicon oxycarbide (SiOC)).

In an example embodiment, an upper surface of the lower portion of the conductive filling pattern 850 may be substantially coplanar with uppermost surfaces of the first and second lower spacers 810 and 820.

The second capping pattern 860 may cover a sidewall of the upper portion of the conductive filling pattern 850 and the upper surface of the lower portion of the conductive filling pattern 850, and the insulating filling pattern 870 may be formed on the second capping pattern 860. The second capping pattern 860 may include oxide (e.g., silicon oxide) or insulating nitride (e.g., silicon nitride), and the insulating filling pattern 870 may include insulating nitride (e.g., silicon nitride).

The bit line structure 395 may include an adhesion pattern 245, a third conductive pattern 265, a second mask 275, a third etch stop pattern 365 and a first capping pattern 385 sequentially stacked on the filling structure in the vertical direction. The adhesion pattern 245 and the third conductive pattern 265 may collectively form a conductive structure, and the second mask 275, the third etch stop pattern 365 and the first capping pattern 385 may collectively form an insulation structure. In an example embodiment, the second mask 275, the third etch stop pattern 365 and the first capping pattern 385 sequentially stacked may be merged with each other to form a single insulation structure.

The adhesion pattern 245 may include metal nitride (e.g., titanium nitride, tantalum nitride, or tungsten nitride), the third conductive pattern 265 may include metal (e.g., tungsten, titanium, tantalum, or ruthenium), and each of the second mask 275, the third etch stop pattern 365 and the first capping pattern 385 may include insulating nitride (e.g., silicon nitride).

In some example embodiments, the bit line structure 395 may extend in the second direction D2 on the filling structure and the third insulation pad 775, and a plurality of bit line structures may be spaced apart from each other in the first direction D1.

The adhesion pattern 245 may be formed between the third insulation pad 775 including insulating nitride (e.g., silicon nitride) and the third conductive pattern 265 including metal (e.g., tungsten), and may connect the third insulation pad 775 and the third conductive pattern 265.

The second contact plug structure may include a second contact plug 930, a second ohmic contact pattern 500 and a third contact plug 549 sequentially stacked on the conductive pad structure 730 in the vertical direction.

The second contact plug 930 may contact the third conductive pad 720 to be electrically connected to the active pattern 103. In some example embodiments, a plurality of second contact plugs 930 may be spaced apart from each other in the second direction D2 between neighboring ones of the bit line structures 395 in the first direction D1, and the third capping pattern 940 may be formed between neighboring ones of the second contact plugs 930 in the second direction D2. The third capping pattern 940 may include an insulating nitride (e.g., silicon nitride).

The second contact plug 930 may include, for example, doped polysilicon, and the second ohmic contact pattern 500 may include metal silicide (e.g., titanium silicide, cobalt silicide, or nickel silicide).

In an example embodiment, the third contact plug 549 may include a third metal pattern 545 and a second barrier pattern 535 covering a lower surface and a sidewall of the third metal pattern 545. In some example embodiments, a plurality of third contact plugs 549 may be spaced apart from each other in the first and second directions D1 and D2, and may be arranged in a honeycomb pattern or a lattice pattern in a plan view. Each of the third contact plugs 549 may have a shape of a circle, an ellipse, a polygon, etc., in a plan view.

The upper spacer structure 915 may include a first upper spacer 880 covering a sidewall of the bit line structure and portions of upper surfaces of the second capping pattern 860 and the insulating filling pattern 870 included in the filling structure, an air spacer 895 on an outer sidewall of the first upper spacer 880, and a third upper spacer 900 covering an outer sidewall of the air spacer 895 and portions of upper surfaces of the second capping pattern 860 and the insulating filling pattern 870 included in the filling structure.

The first upper spacer 880 may include an insulating nitride (e.g., silicon nitride), the air spacer 895 may include air, and the third upper spacer 900 may include insulating nitride (e.g., silicon nitride).

The fourth upper spacer 490 may be formed on a portion of the first upper spacer 880 on an upper sidewall of the bit line structure 395, and may cover a top of the air spacer 895 and at least a portion of the upper surface of the third upper spacer 900.

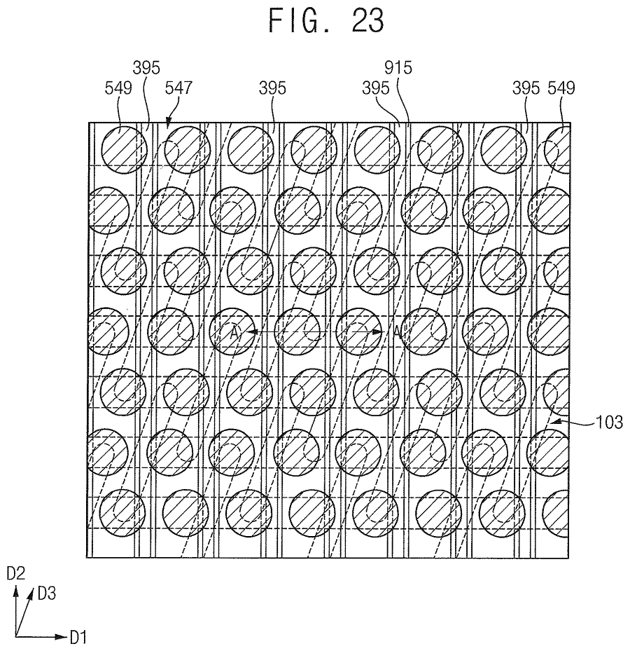

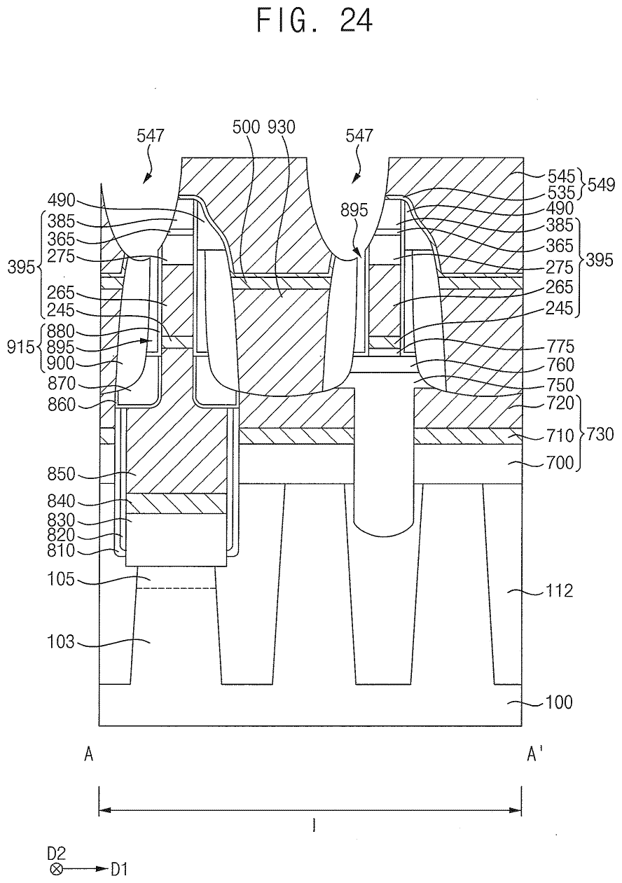

Referring to FIGS. 23 and 24, the insulation pattern structure may include a first insulation pattern 615 and a second insulation pattern 620. The first insulation pattern 615 may be formed on an inner wall of a seventh opening 547 that may penetrate through the third contact plug 549, a portion of the insulation structure included in the bit line structure 395, and portions of the first, third and fourth spacers 880, 900 and 490 and surround the third contact plug 549 in a plan view. The second insulation pattern 620 may be formed in a remaining portion of the seventh opening 547. A top end of the air spacer 895 may be closed by the first insulation pattern 615.

The first and second insulation patterns 615 and 620 may include an insulating nitride (e.g., silicon nitride).

The fourth etch stop layer 630 may be formed on the first and second insulation patterns 615 and 620, the third contact plug 549 and the third capping pattern 940.

The capacitor 670 may be formed on the third contact plug 549, and may include a lower electrode 640 having a pillar shape or a cylindrical shape, a dielectric layer 650 on a surface of the lower electrode 640, and an upper electrode 660 on the dielectric layer 650.

The lower electrode 640 may include, for example, metal, metal nitride, metal silicide, or doped polysilicon, the dielectric layer 650 may include, for example, metal oxide, the upper electrode 660 may include, for example, metal, metal nitride, metal silicide, or doped silicon-germanium. In an example embodiment, the upper electrode 660 may include a first electrode including metal or metal nitride, and a second upper electrode including doped silicon-germanium.

The semiconductor device may include the fourth conductive pad 830 between the upper surface of the active pattern 103 and the first ohmic contact pattern 840, and areas (e.g., widths) of the lower surface and the upper surface of the fourth conductive pad 830 may be greater than an area (e.g., a width) of the upper surface of the active pattern 103. As illustrated below, even if the area of the upper surface of the active pattern 103 is small, the first ohmic contact pattern 840 may be easily formed on the fourth conductive pad 830 having the area greater than the area of the upper surface of the active pattern 103.

As shown in FIG. 2B, if the second opening 805 exposing the upper surface of the active pattern 103 is formed to partially expose the upper surface of the active pattern 103 due to the misalignment, and thus, even though the area of the upper surface of the active pattern 103 exposed by the second opening 805 is very small, the fourth conductive pad 830 having the area greater than the area of the exposed upper surface of the active pattern 103 may be formed on the exposed upper surface of the active pattern 103, so that the first ohmic contact pattern 840 may be easily formed on the fourth conductive pad 830 having the relatively large area.

Thus, the total resistance between the conductive filling pattern 850 and the active pattern 103 may decrease due to the first ohmic contact pattern 840.

FIGS. 3 to 24 are plan views and cross-sectional views illustrating a method of manufacturing a semiconductor device in accordance with an example embodiment. Particularly, FIGS. 3, 5, 7, 19 and 23 are the plan views, FIG. 4 includes cross-sections taken along lines A-A′ and B-B′ of FIG. 3, and FIGS. 6, 8-18, 20-22 and 24 are cross-sectional views taken along lines A-A′ of corresponding plan views, respectively.

Referring to FIGS. 3 and 4, an active pattern 103 may be formed on a substrate 100, and an isolation pattern 112 may be formed to cover a sidewall of the active pattern 103.

The active pattern 103 may be formed by removing an upper portion of the substrate 100 to form a first recess, and a plurality of active patterns 103 each of which may extend in the third direction D3 may be formed to be spaced apart from each other in the first and second directions D1 and D2.

The active pattern 103 and the isolation pattern 112 may be partially etched to form a second recess extending in the first direction D1.

A gate structure may be formed in the second recess. In example embodiments, the gate structure 170 may extend in the first direction D1, and a plurality of gate structures 170 may be formed to be spaced apart from each other in the second direction D2.

Referring to FIGS. 5 and 6, a conductive pad structure 730 may be formed on the active pattern 103 and the isolation pattern 112.

The conductive pad structure 730 may include first, second and third conductive pads 700, 710 and 720 sequentially stacked in the vertical direction.

The conductive pad structure 730 may be patterned by an etching process to form a first opening 740 exposing upper surfaces of the active pattern 103, the isolation pattern 112 and the gate structure 170, and during the etching process, upper portions of the active pattern 103 and the isolation pattern 112 may also be partially removed.

In some example embodiments, the first opening 740 may include a first portion extending in the first direction D1 and a second portion extending in the second direction D2 that may be connected with each other. Thus, a plurality of conductive pad structures 730 may be spaced apart from each other to be arranged in a lattice pattern in a plan view.

In some example embodiments, the conductive pad structure 730 may overlap in the vertical direction an end portion of the active pattern 103 extending in the third direction D3 and a portion of the isolation pattern 112 adjacent thereto in the first direction D1.

Referring to FIGS. 7 and 8, an insulation pad layer structure 780 may be formed on the conductive pad structure 730 to fill the first opening 740.

In example embodiments, the insulation pad layer structure 780 may include first, second and third insulation pad layers 750, 760 and 770 sequentially stacked, and the first insulation pad layer 750 may fill the first opening 740.

First and second etch stop layers 790 and 800 may be sequentially formed on the insulation pad layer structure 780. In some example embodiments, the first etch stop layer 790 may be formed by a nitridation process on the third insulation pad layer 770 included in the insulation pad layer structure 780 and may include, for example, silicon oxynitride (SiON). The second etch stop layer 800 may be formed on the first etch stop layer 790 by a deposition process, for example, a chemical vapor deposition (CVD) process or an atomic layer deposition (ALD) process and may include an insulating nitride, e.g., silicon nitride.

A first mask (not shown) may be formed on the second etch stop layer 800, and the first and second etch stop layers 790 and 800, the insulation pad layer structure 780, the conductive pad structure 730, the active pattern 103, the isolation pattern 112 and the gate mask 160 included in the gate structure 170 may be partially etched by an etching process using the first mask as an etching mask to form a second opening 805, and an upper surface of a portion of the active pattern 103 may be exposed by the second opening 805.

In some example embodiments, the first mask may have a shape of, e.g., a circle or an ellipse in a plan view, and a plurality of first masks may be spaced apart from each other in the first and second directions D1 and D2. Each of the first masks may overlap in the vertical direction end portions of neighboring ones of the active patterns 103 in the first direction D1 and a portion of the isolation pattern 112 therebetween.

For example, an ion implantation process may be performed on the exposed portion of the active pattern 103 to form an impurity region 105. The impurity region 105 may include, for example, n-type impurities or p-type impurities.

The first mask may be removed.

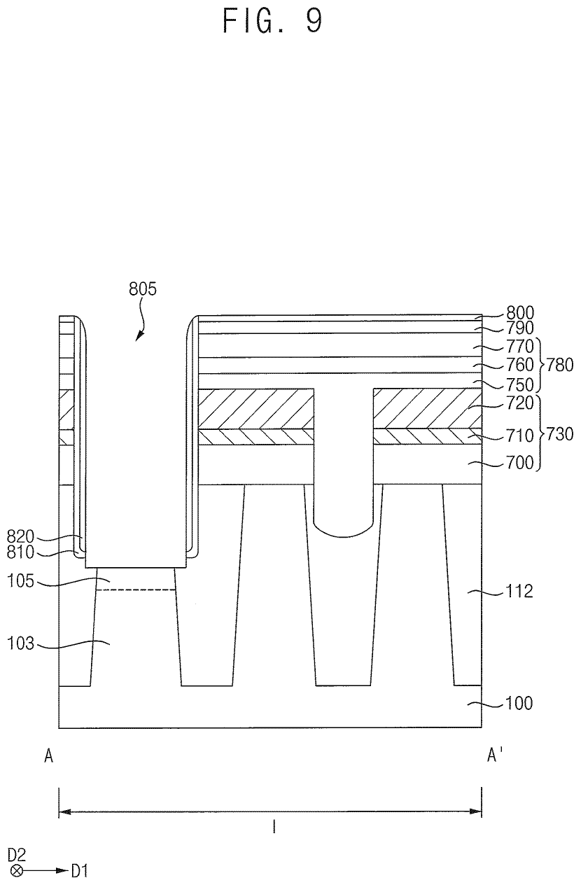

Referring to FIG. 9, first and second lower spacer layers may be sequentially formed on a sidewall and a bottom of the second opening 805 and an upper surface of the second etch stop layer 800, and an anisotropic etching process may be performed on the first and second lower spacer layers.

Thus, a lower spacer structure including first and second lower spacers 810 and 820 may be formed on the sidewall of the second opening 805, and the upper surface of the active pattern 103 and the portion of the isolation pattern 112 adjacent thereto may be exposed again.

During the anisotropic etching process, a portion of the active pattern 103 and a portion of the isolation pattern 112 adjacent thereto may be partially removed, and the second etch stop layer 800 may be partially or entirely removed.

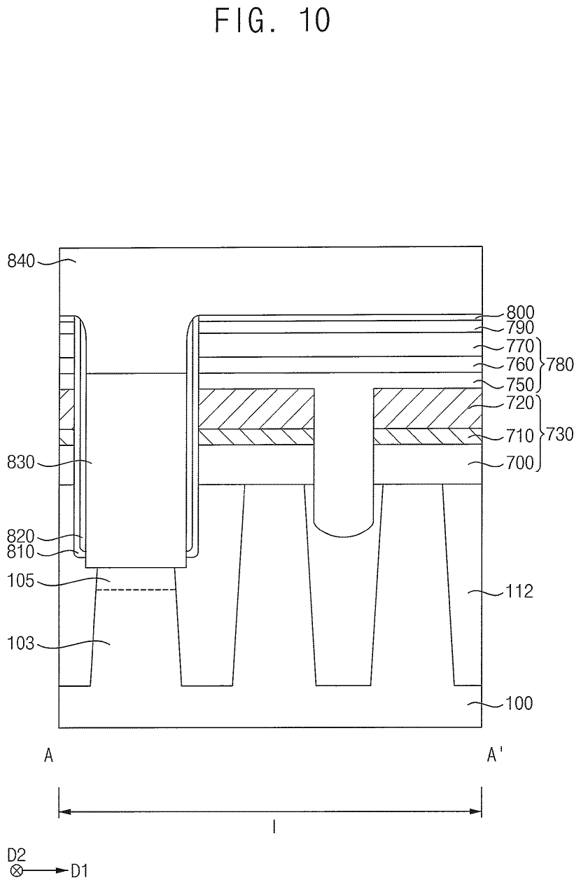

Referring to FIG. 10, a fourth conductive pad 830 including single crystalline silicon doped with n-type or p-type impurities or polysilicon doped with n-type or p-type impurities may be formed on the impurity region 105 to fill a lower portion of the second opening 805.

In an example embodiment, the fourth conductive pad 830 may be formed by a selective epitaxial growth (SEG) process using an upper portion of the exposed active pattern 103, that is, using an upper portion of the impurity region 105 as a seed. An upper surface of the fourth conductive pad 830 may have a crystal orientation according to a crystal orientation of the active pattern 103, and the fourth conductive pad 830 may include doped single crystalline silicon.

Due to the characteristics of the SEG process, the fourth conductive pads 830 on the active patterns 103, respectively, may have upper surfaces that are not coplanar with each other.

In some example embodiments, the fourth conductive pad 830 may be formed by forming a fourth conductive pad layer through a deposition process on the bottom and the sidewall of the second opening 805 and the upper surface of the second etch stop layer 800, and etching an upper portion of the fourth conductive pad layer. In this case, the fourth conductive pad 830 may include doped polysilicon, and a seam or void may be formed in the fourth conductive pad 830.

In some example embodiments, the SEG process, the deposition process and the etching process may be sequentially performed to form the fourth conductive pad 830.

A first sacrificial layer 840 may be formed on the fourth conductive pad 830, the first and second lower spacers 810 and 820 and the second etch stop layer 800, and a planarization process may be performed on the first sacrificial layer 840.

The first sacrificial layer 840 may include a material that may be substantially the same as or similar to the material of the fourth conductive pad 830. For example, the first sacrificial layer 840 may include doped or undoped polysilicon.

The planarization process may include a chemical mechanical polishing (CMP) process.

Referring to FIG. 11, the first sacrificial layer 840 and an upper portion of the fourth conductive pad 830 may be removed.

In some example embodiments, the first sacrificial layer 840 and the upper portion of the fourth conductive pad 830 may be removed by an etch back process. If the second etch stop layer 800 partially remains during the anisotropic etching process for forming the lower spacer structure, the remaining portion of the second etch stop layer 800 may be removed by the etch back process, and the first etch stop layer 790 may remain during the etch back process to cover the insulation pad layer structure 780.

As illustrated above, if the fourth conductive pads 830 are formed by a SEG process, the fourth conductive pads 830 on the active patterns 103, respectively, may have various crystal orientations according to the crystal orientations of the active patterns 103, and the upper surfaces of the fourth conductive pads 830 may have different heights according to growth rates thereof. However, in some example embodiments, after forming the first sacrificial layer 840 on the fourth conductive pads 830, the fourth conductive pads 830 may have upper surfaces that may be substantially coplanar with each other by removing the first sacrificial layer 840 and the upper portions of the fourth conductive pads 830.

After the etch back process, a cleansing process may be further performed, and the second lower spacer 820 may protect the first lower spacer 810.

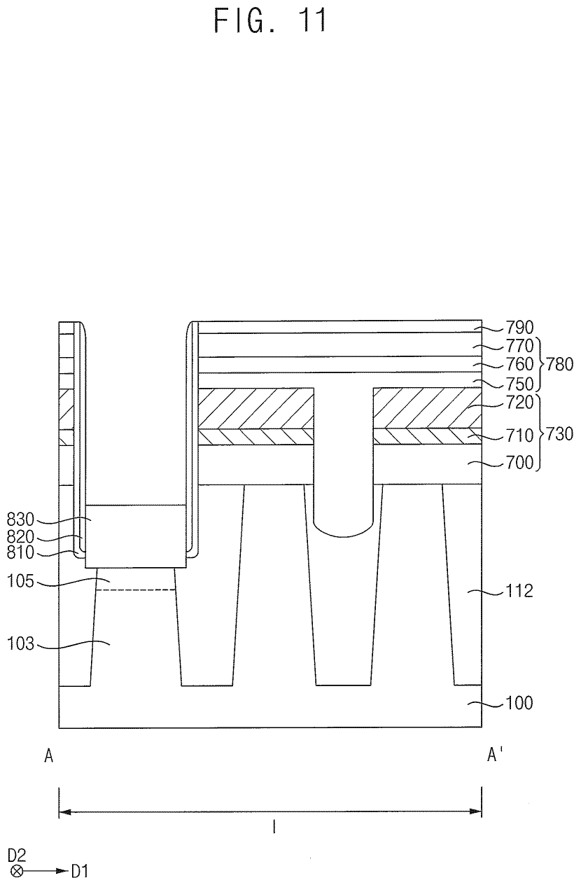

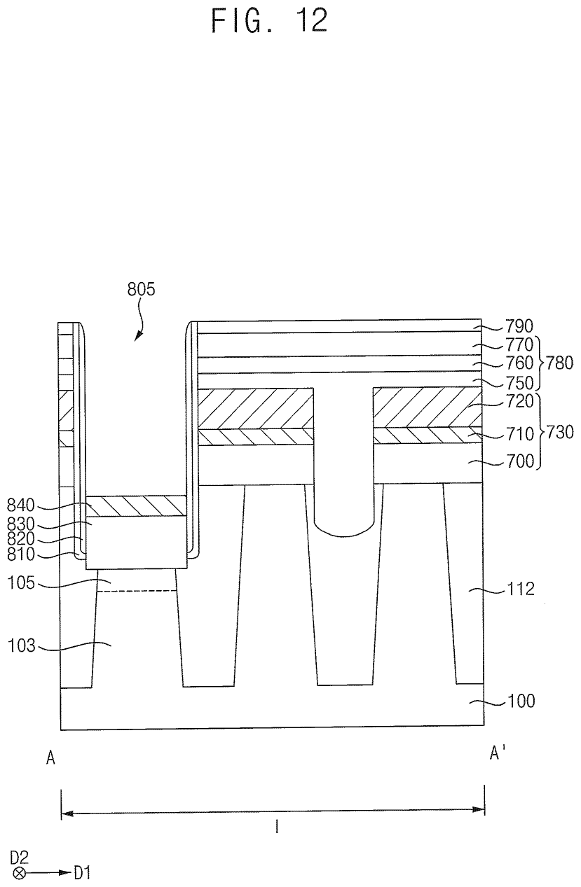

Referring to FIG. 12, a first ohmic contact pattern 840 may be formed on the fourth conductive pad 830.

In some example embodiments, the first ohmic contact pattern 840 may be formed by forming a first metal layer on the fourth conductive pad 830, the first and second lower spacers 810 and 820 and the first etch stop layer 790, performing a heat treatment process on the first metal layer so that the first metal layer and the fourth conductive pad 830 may be reacted with each other, and removing an unreacted portion of the first metal layer.

The first ohmic contact pattern 840 may include a metal silicide (e.g., titanium silicide, cobalt silicide, or nickel silicide).

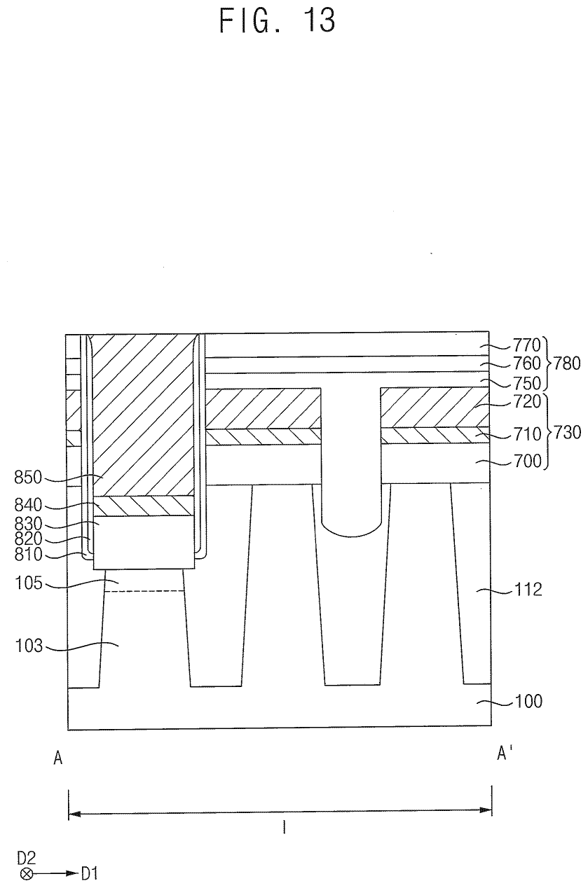

Referring to FIG. 13, a conductive filling pattern 850 may be formed on the first ohmic contact pattern 840 to fill a remaining portion of the second opening 805.

The conductive filling pattern 850 may be formed by forming a conductive filling layer on the first ohmic contact pattern 840, the first and second lower spacers 810 and 820 and the first etch stop layer 790 to fill the second opening 805, and performing an etch back process and/or a chemical mechanical polishing (CMP) process. Thus, the conductive filling pattern 850 may be formed in an upper portion of the second opening 805.

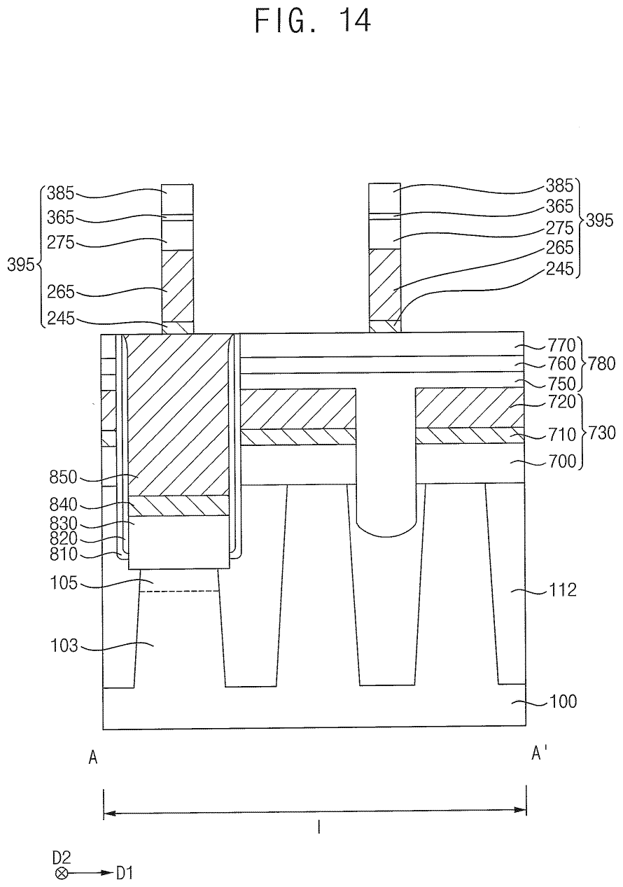

Referring to FIG. 14, an adhesion layer, a third conductive layer, a second mask layer, a third etch stop layer and a first capping layer may be sequentially formed on the insulation pad layer structure 780, the first capping layer may be patterned to form a first capping pattern 385, and the third etch stop layer, the second mask layer, the third conductive layer and the adhesion layer may be sequentially etched using the first capping pattern 385 as an etching mask.

By the etching process, an adhesion pattern 245, a third conductive pattern 265, a second mask 275, a third etch stop pattern 365 and the first capping pattern 385 sequentially stacked may be formed on the conductive filling pattern 850 and the insulation pad layer structure 780.

The adhesion pattern 245 may be formed between the third insulation pad layer 770 including insulating nitride (e.g., silicon nitride) and the third conductive pattern 265 including metal (e.g., tungsten) so that the third insulation pad layer 770 and the third conductive pattern 265 may be attached to each other.

Hereinafter, the adhesion pattern 245, the third conductive pattern 265, the second mask 275, the third etch stop pattern 365, and the first capping pattern 385 sequentially stacked may be referred to as a bit line structure 395. The bit line structure 395 may include a conductive structure having the adhesion pattern 245 and the third conductive pattern 265, and an insulation structure having the second mask 275, the third etch stop pattern 365, and the first capping pattern 385 on the conductive structure. In an example embodiment, second mask 275, the third etch stop pattern 365, and the first capping pattern 385 may be merged to form a single insulation structure.

In some example embodiments, the bit line structure 395 may extend in the second direction D2 on the substrate 100, and a plurality of bit line structures 395 may be spaced apart from each other in the first direction D1.

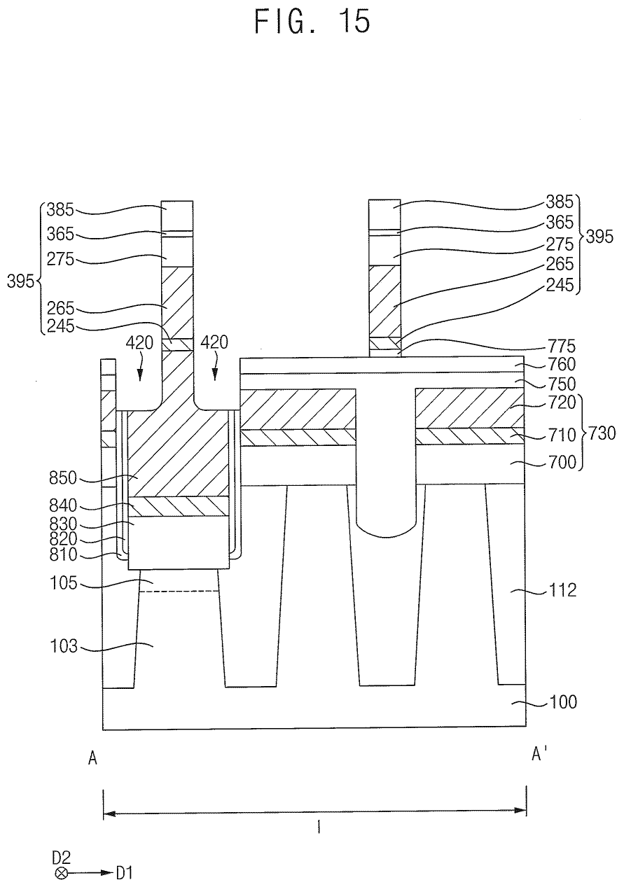

Referring to FIG. 15, upper portions of the conductive filling pattern 850 and the first and second lower spacers 810 and 820 that are not covered by the bit line structure 395 may be removed by an etching process to form a third recess 420.

By the etching process, the conductive filling pattern 850 may include a lower portion having a relatively large width and an upper portion having a relatively small width on the lower portion. In an example embodiment, an upper surface of the lower portion of the conductive filling pattern 850 may be substantially coplanar with uppermost surfaces of the first and second lower spacers 810 and 820.

During the etching process, a portion of the third insulation pad layer 770 that is not covered by the bit line structure 395 may also be removed, and thus an upper surface of the second insulation pad layer 760 may be exposed. However, a portion of the third insulation pad layer 770 between the second insulation pad layer 760 and the bit line structure 395 may remain as a third insulation pad 775.

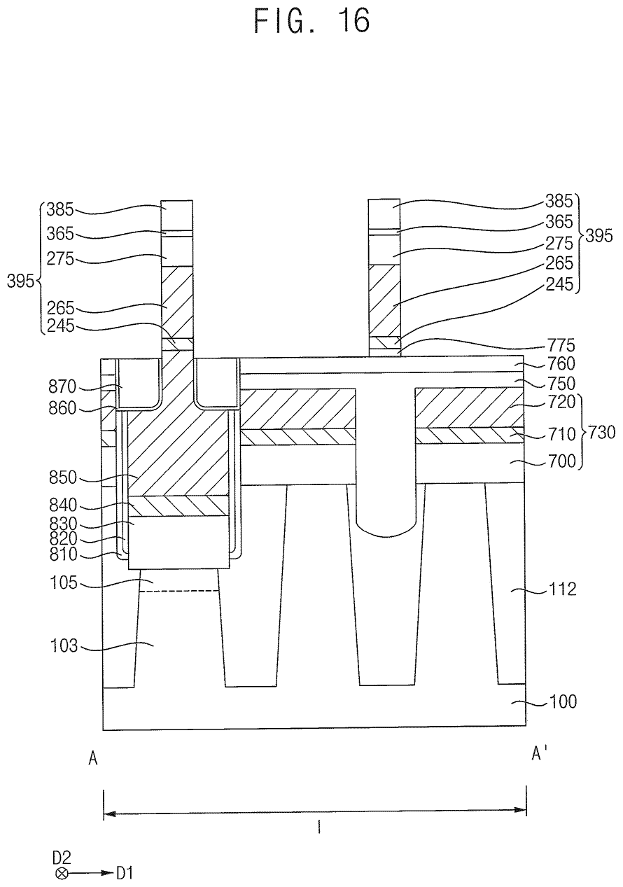

Referring to FIG. 16, a second capping layer may be formed on the bit line structure 395, the conductive filling pattern 850, the first and second lower spacers 810 and 820, the first and second insulation pad layers 750 and 760 and the third insulation pad 775 by, for example, an atomic layer deposition (ALD) process. Then, an insulation filling layer may be formed on the second capping layer to fill the third recess 420, and upper portions of the insulation filling layer and the second capping layer may be removed by an etching process until the upper surface of the second insulation pad layer 760 is exposed.

During the etching process, a portion of the second capping layer at an outside of the third recess 420 may also be removed, and thus an upper surface and a sidewall of the bit line structure 395, the upper surface of the second insulation pad layer 760 and a sidewall of the third insulation pad 775 may be exposed.

Thus, a second capping pattern 860 may remain on the inner wall of the third recess 420, and an insulating filling pattern 870 may be formed on the second capping pattern 860. The first and second lower spacers 810 and 820, the fourth conductive pad 830, the first ohmic contact pattern 840, the conductive and insulating filling patterns 850 and 870, and the second capping pattern 860 in the second opening 805 may collectively form a filling structure. The fourth conductive pad 830, the first ohmic contact pattern 840 and the conductive filling pattern 850 sequentially stacked in the vertical direction may collectively form a first contact plug structure.

Referring to FIG. 17, first and second upper spacer layers may be sequentially formed on the substrate 100 having the bit line structure 395, the second insulation pad layer 760, the third insulation pad 775 and the filling structure thereon, and may be anisotropically etched to form a first upper spacer 880 on a sidewall of the bit line structure 395 and upper surfaces of portions of the second capping pattern 860 and the insulating filling pattern 870 included in the filling structure, and a second upper spacer 890 on an outer sidewall of the first upper spacer 880.

A dry etching process may be performed using the bit line structure 395 and the first and second upper spacers 880 and 890 as an etching mask to form a third opening 440 extending partially through the second capping pattern 860, the insulating filling pattern 870, the second insulation pad layer 760 and the first insulation pad layer 750 to partially expose an upper surface of the third conductive pad 720.

A third upper spacer layer may be formed on upper surfaces of the first capping pattern 385 and the first upper spacer 880, an upper surface and an outer sidewall of the second upper spacer 890, an upper surface of a portion of the filling structure, and sidewalls of the first and second insulation pad layers 750 and 760 and an upper surface of the third conductive pad 720 exposed by the third opening 440, and may be anisotropically etched to form a third upper spacer 900 covering the outer sidewall of the second upper spacer 890. The third upper spacer 900 may also cover the upper surface of the portion of the filling structure.

The first to third upper spacers 880, 890 and 900 sequentially stacked on the sidewall of the bit line structure 395 may collectively form a preliminary upper spacer structure 910.

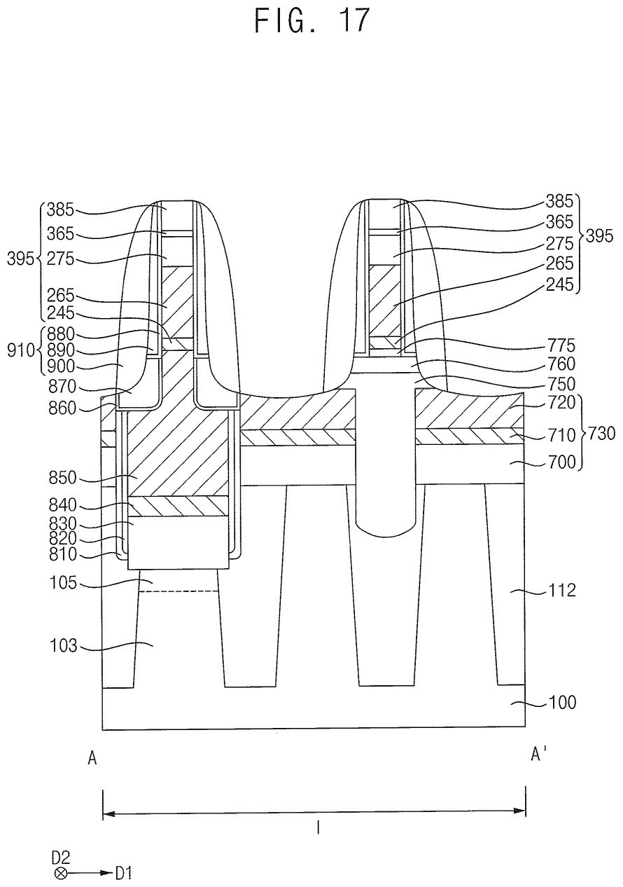

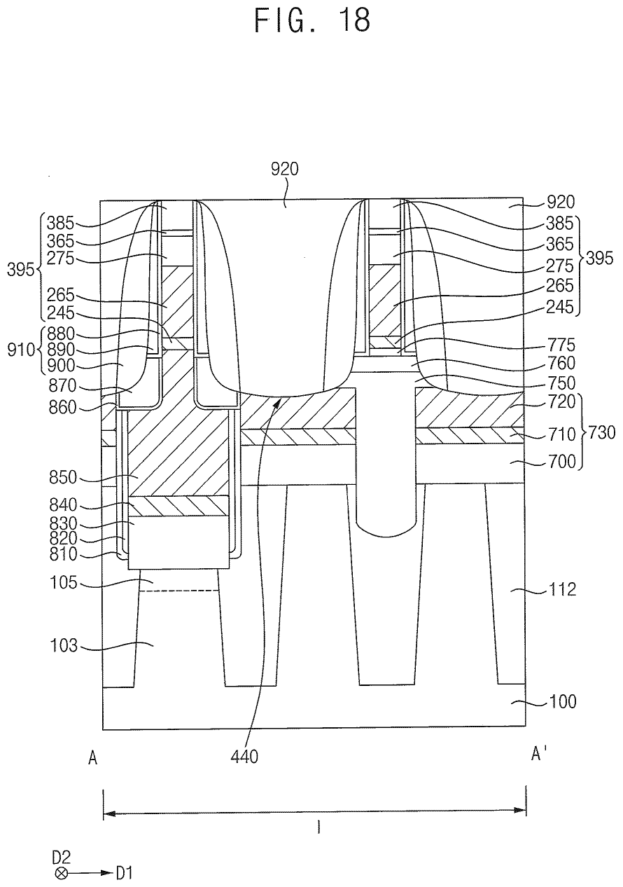

Referring to FIG. 18, a second sacrificial layer may be formed to a sufficient height to fill the third opening 440 on the substrate 100, and may be planarized until the upper surface of the first capping pattern 385 is exposed to form a second sacrificial pattern 920. In some example embodiments, the second sacrificial pattern 920 may extend in the second direction D2, and a plurality of second sacrificial patterns 920 may be spaced apart from each other in the first direction D1 by the bit line structures 395. The second sacrificial pattern 920 may include oxide (e.g., silicon oxide).

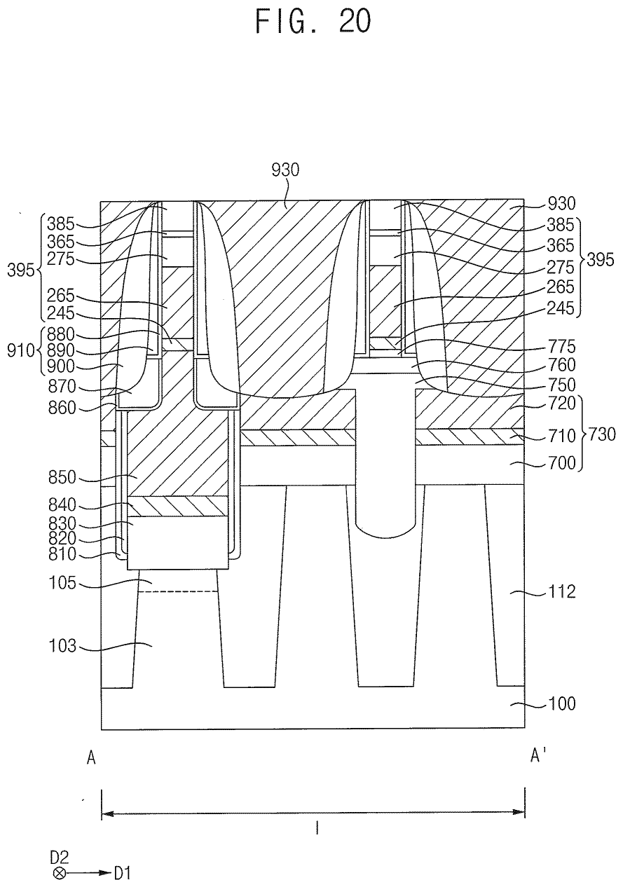

Referring to FIGS. 19 and 20, a third mask having a plurality of fourth openings, which are spaced apart from each other in the second direction D2and extend in the first direction D1, may be formed on the first capping pattern 385, the second sacrificial pattern 920 and the preliminary upper spacer structure 910. The second sacrificial pattern 920 may be etched using the third mask as an etching mask to form a fifth opening exposing an upper surface of the gate mask 160 of the gate structure 170.

In some example embodiments, each of the fifth openings may overlap the gate structure 170 in the vertical direction, and a plurality of the fifth openings may be spaced apart from each other in the second direction D2 between the bit line structures 395 neighboring in the first direction D1.

After removing the third mask, a third capping pattern 940 may be formed to fill the fifth openings. According to a layout of the fifth openings, a plurality of third capping patterns 940 may be spaced apart from each other in the second direction D2 between the bit line structures 395 neighboring in the first direction D1. The third capping pattern 940 may include insulating nitride (e.g., silicon nitride).

The plurality of second sacrificial patterns 920 may be spaced apart from each other in the second direction D2 between the bit line structures 395.

The remaining second sacrificial pattern 920 may be removed to form a sixth opening partially exposing the upper surface of the third conductive pad 720. A plurality of the sixth openings may be spaced apart from each other in the second direction D2 between the bit line structures 395 neighboring in the first direction D1.

A second contact plug layer may be formed to a sufficient height to fill the sixth openings, and may be planarized until the upper surface the first capping pattern 385 and upper surfaces of the third capping pattern 940 and the preliminary upper spacer structure 910 are exposed. Accordingly, the second contact plug layer may be divided into a plurality of second contact plugs 930, which may be spaced apart from each other in the second direction D2 by the third capping patterns 940 between the bit line structures 395.

The second contact plug 930 may include, for example, doped polysilicon, and may be electrically connected to the active pattern 103 by contacting the third conductive pad 720.

Referring to FIG. 21, an upper portion of the second contact plug 930 may be removed to expose an upper portion of the preliminary upper spacer structure 910 on the sidewall of the bit line structure 395, and upper portions of the second and third upper spacers 890 and 900 of the exposed preliminary upper spacer structure 910 may be removed.

The upper portion of the second contact plug 930 may be removed by, for example, an etch back process, and the upper portions of the second and third upper spacers 890 and 900 may be removed by, for example, a wet etching process.

A fourth upper spacer layer may be formed on the bit line structure 395, the preliminary upper spacer structure 910, the second contact plug 930 and the third capping pattern 940, and may be anisotropically etched to form a fourth upper spacer 490. The fourth upper spacer 490 may be formed on a portion of an outer sidewall of the first upper spacer 880 on an upper sidewall of the bit line structure 395.

The fourth upper spacer 490 that may be formed by the anisotropic etching process may cover an upper surface of the second upper spacer 890 and at least a portion of an upper surface of the third upper spacer 900. Thus, during the anisotropic etching process, an upper portion of the second contact plug 930 may be partially removed, and a portion of the third upper spacer 900 not covered by the fourth upper spacer 490 may also be removed.

In an example embodiment, a fifth upper spacer layer may be formed on the bit line structure 395, the first upper spacer 880, the fourth upper spacer 490, the second contact plug 930 and the third capping pattern 940, and may be further etched to form a fifth upper spacer (not shown) on a sidewall of the fourth upper spacer 490, and the upper portion of the second contact plug 930 may be additionally etched using the bit line structure 395, the first upper spacer 880, the fourth upper spacer 490, the second contact plug 475 and the third capping pattern 940 as an etching mask. Thus, an upper surface of the second contact plug 930 may be lower than uppermost surfaces of the second and third upper spacers 890 and 900.

A second ohmic contact pattern 500 may be formed on the upper surface of the second contact plug 475. In some example embodiments, the second ohmic contact pattern 500 may be formed by forming a second metal layer on the bit line structure 395, the first upper spacer 880, the fourth upper spacer 490, the third upper spacer 900, the second contact plug 930 and the third capping pattern 485, and performing a heat treatment on the second metal layer, that is, by performing a silicidation process in which the second metal layer including metal and the second contact plug 930 including silicon are reacted with each other, and removing an unreacted portion of the second metal layer.

The second ohmic contact pattern 500 may include, for example, cobalt silicide, nickel silicide, or titanium silicide.

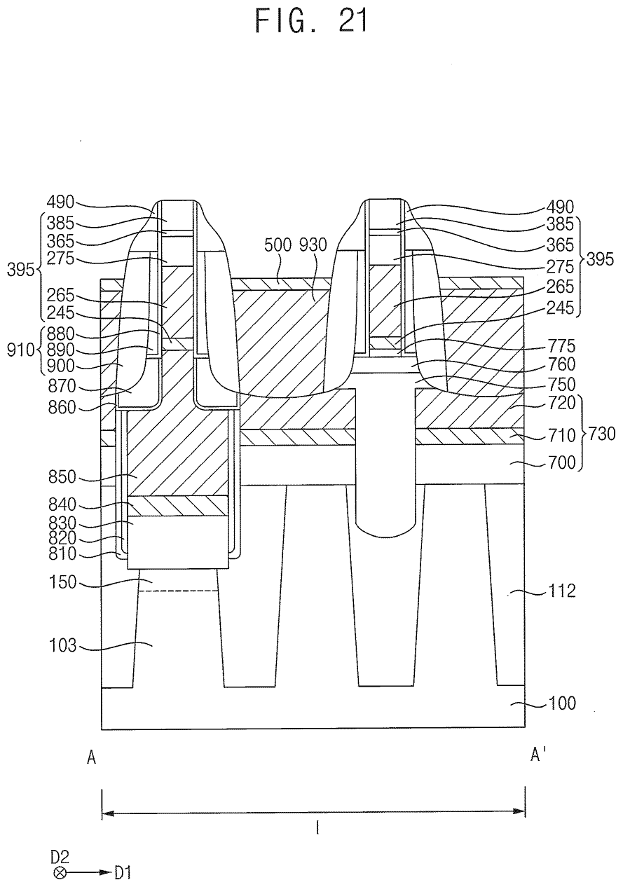

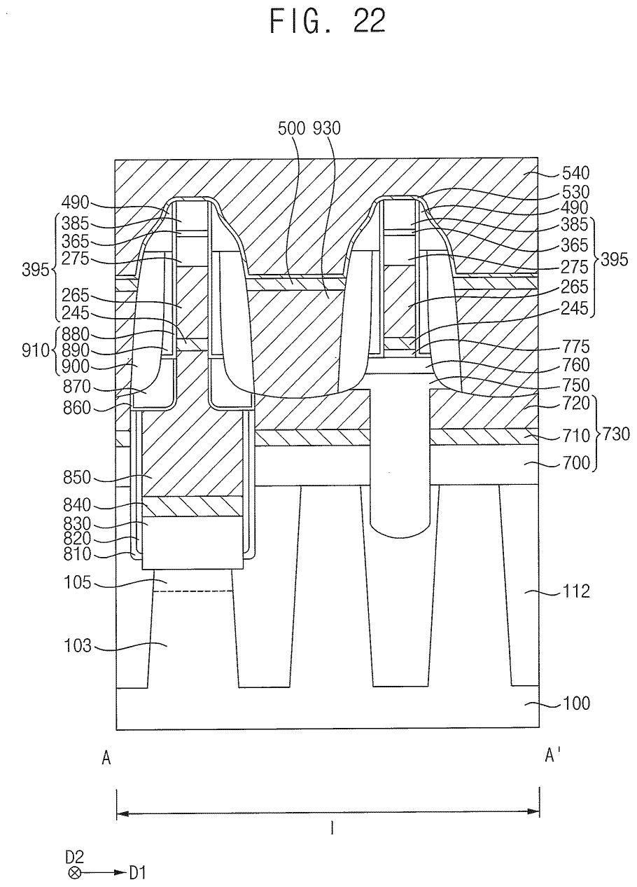

Referring to FIG. 22, a second barrier layer 530 may be formed on the bit line structure 395, the first upper spacer 880, the fourth upper spacer 490, the third upper spacer 900, the second ohmic contact pattern 500 and the third capping pattern 940, and a third metal layer 540 may be formed on the second barrier layer 530 to fill a space between the bit line structures 395.

A planarization process may be performed on an upper portion of the third metal layer 540. The planarization process may include a CMP process and/or an etch back process.

Referring to FIGS. 23 and 24, the third metal layer 540 and the second barrier layer 530 may be patterned to form a third contact plug 549, and a seventh opening 547 may be formed between a plurality of third contact plugs 549.

During the formation of the seventh opening 547, not only the third metal layer 540 and the second barrier layer 530 but also an upper portion of the insulation structure included in the bit line structure 395, the preliminary spacer structure 910 and the fourth spacer 490 on the sidewall thereof, and the third capping pattern 940 may also be partially removed, and thus an upper surface of the second upper spacer 890 may be exposed.

As the seventh opening 547 is formed, the third metal layer 540 and the second barrier layer 530 may be transformed, respectively, into a third metal pattern 545 and a second barrier pattern 535 covering a lower surface and a sidewall of the third metal pattern 545, which may form a third contact plug 549. In some example embodiments, the plurality of third contact plugs 549 may be spaced apart from each other in the first and second directions D1 and D2, and may be arranged in a honeycomb pattern or a lattice pattern in a plan view. Each of the third contact plugs 549 may have a shape of a circle, an ellipse, or a polygon in a plan view.

The second contact plug 930, the second ohmic contact pattern 500 and the third contact plug 549 sequentially stacked on the substrate 100 may form a second contact plug structure.

The exposed second upper spacer 890 may be removed to form an air gap 895 connected with the seventh opening 547. The second upper spacer 890 may be removed by, for example, a wet etching process.

In some example embodiments, not only a portion of the second upper spacer 890 directly exposed by the seventh opening 547 but also a portion of the second upper spacer 890 parallel thereto may be removed. That is, not only the portion of the second upper spacer 890 exposed by the seventh opening 547 that is not covered by the third contact plug 549 but also a portion of the second upper spacer 890 that is covered by the third contact plug 549 may be removed.

Referring to FIGS. 1 and 2 again, a first insulation pattern 615 may be formed on an inner wall of the seventh opening 547, and a second insulation pattern 620 may be formed on the first insulation pattern 615 to fill a remaining portion of the seventh opening 547. Thus, a top end of the air gap 895 may be closed by the first and second insulation patterns 615 and 620.

The air gap 895 may also be referred as an air spacer 895, and the first upper spacer 880, the air spacer 895 and the third upper spacer 900 may collectively form an upper spacer structure 915.

The first and second insulation patterns 615 and 620 may form an insulation pattern structure.

A fourth etch stop layer 630 may be formed on the first and second insulation patterns 615 and 620, the third contact plug 549 and the third capping pattern 940, and a mold layer may be formed on the fourth etch stop layer 630. A portion of the mold layer and a portion of the fourth etch stop layer 630 thereunder may be partially etched to form an eighth opening exposing an upper surface of the third contact plug 549.

As the plurality of third contact plugs 549 is spaced apart from each other in the first and second directions D1 and D2, and may be arranged in a honeycomb pattern or a lattice pattern in a plan view, the eighth openings exposing the third contact plugs 549 may also be arranged in a honeycomb pattern or a lattice pattern in a plan view.

A lower electrode layer may be formed on a sidewall of the eighth opening, the exposed upper surface of the third contact plug 549 and the mold layer, a third sacrificial layer may be formed on the lower electrode layer to fill the eighth opening, and the lower electrode layer and the third sacrificial layer may be planarized until an upper surface of the mold layer is exposed to divide the lower electrode layer into a plurality of parts.

Thus, a lower electrode 640 having a shape of a cylinder may be formed in the eighth opening. However, if the eighth opening has a small width, the lower electrode 640 may have a shape of a pillar.

The third sacrificial layer and the mold layer may be removed by, for example, a wet etching process using, for example, LAL solution.

A dielectric layer 650 may be formed on a surface of the lower electrode 640 and the fourth etch stop layer 630. The dielectric layer 650 may include, for example, metal oxide.

An upper electrode 660 may be formed on the dielectric layer 650. The upper electrode 660 may include, for example, metal, metal nitride, metal silicide, or doped silicon-germanium. In an example embodiment, the upper electrode 660 may have a first upper electrode including metal or metal nitride and a second upper electrode including doped silicon-germanium.

The lower electrode 640, the dielectric layer 650 and the upper electrode 660 may collectively form a capacitor 670.

Upper wirings may be further formed on the capacitor 670 to complete the fabrication of the semiconductor device.

As described above, the second opening 805 may be formed to expose the upper surface of the active pattern 103, the lower spacer structure may be formed on the sidewall of the second opening 805, and the fourth conductive pad 830 may be formed on the upper surface of the active pattern 103. A silicidation process may be performed to form the first ohmic contact pattern 840 on the fourth conductive pad 830.

Thus, if the upper surface of the active pattern 103 exposed by the second opening 805 has a small area (e.g., when the second opening 805 only partially exposes the upper surface of the active pattern 103 due to the misalignment as shown in FIG. 2B), the first ohmic contact pattern 840 that may be formed by the silicidation process may have a very small area or even may not be formed.

However, in some example embodiments, the fourth conductive pad 830 having a lower surface with an area greater than that of the upper surface of the active pattern 103 may be formed in the second opening 805 to contact the upper surface of the active pattern 103, and the silicidation process may be performed on the upper surface of the fourth conductive pad 830 having a relatively large area so that the first ohmic contact pattern 840 having a relatively large area may be easily formed even if the upper surface of the active pattern 103 has a very small area due to the misalignment.

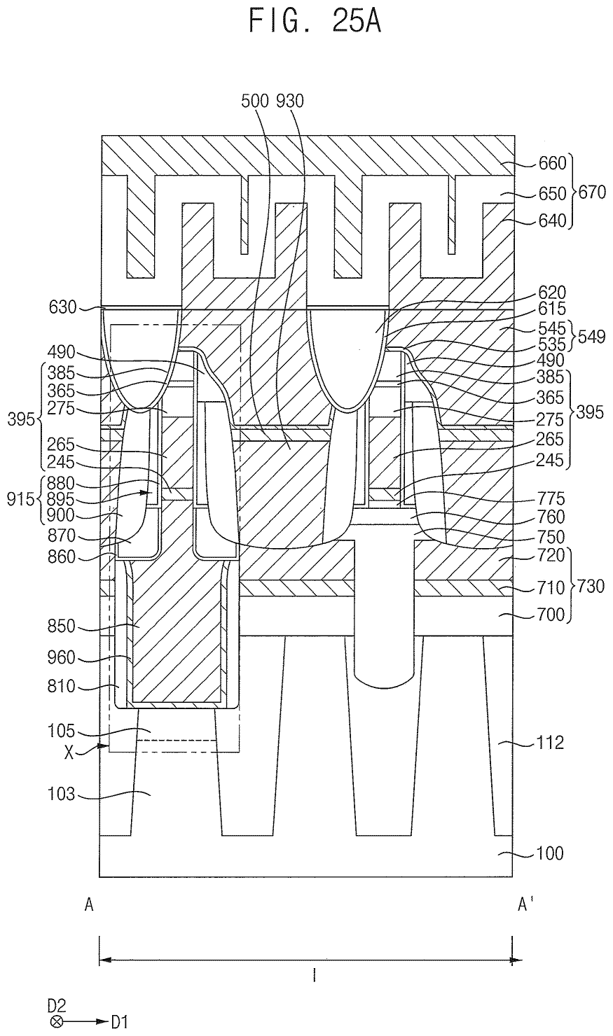

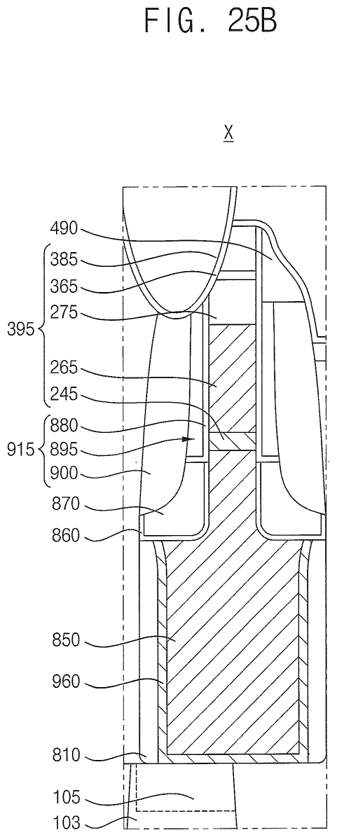

FIGS. 25A and 25B are cross-sectional views illustrating a semiconductor device in accordance with an example embodiment, which correspond to FIGS. 2A and 2B, respectively. FIG. 25B is an enlarged cross-sectional view of region X in FIG. 25A.

This semiconductor device may be substantially the same as or similar to the semiconductor device of FIGS. 1 and 2, and thus repeated explanations are omitted herein.

Referring to FIGS. 25A and 25B, the filling structure may include the first contact plug structure and the lower spacer structure on the sidewall of the first contact plug structure, and the first contact plug structure may include a second ohmic contact pattern 960 on the upper surface of the active pattern 103 and the portion of the isolation pattern 112 adjacent thereto, and the conductive filling pattern 850.

In some example embodiments, the second ohmic contact pattern 960 may cover a lower surface and a sidewall of the lower portion of the conductive filling pattern 850.

The lower spacer structure may include only the first lower spacer 810, and may contact an outer sidewall of the second ohmic contact pattern 960.

The second ohmic contact pattern 960 included in the semiconductor device may be formed in the second opening 805 having a lower surface with an area greater than an area of the active pattern 103 as shown in FIG. 25B, and thus even though the second opening 805 expose only a portion of the upper surface of the active pattern 103 due to the misalignment, the second ohmic contact pattern 960 may have an area greater than the area of the upper surface of the active pattern 103.

The lower spacer structure may include a single layer in the second opening 805 so as to have a relatively small thickness. Accordingly, a space for forming the second ohmic contact pattern 960 and the conductive filling pattern 850 may be easily acquired.

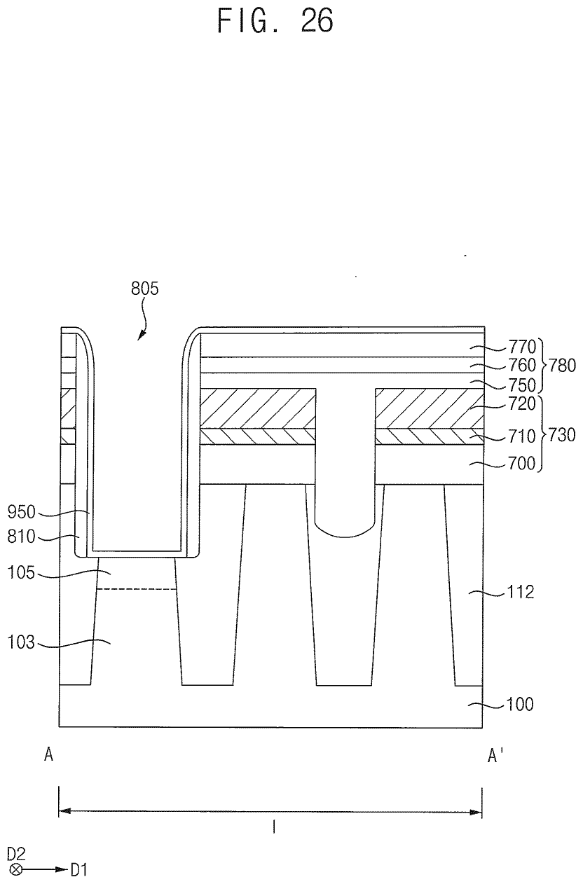

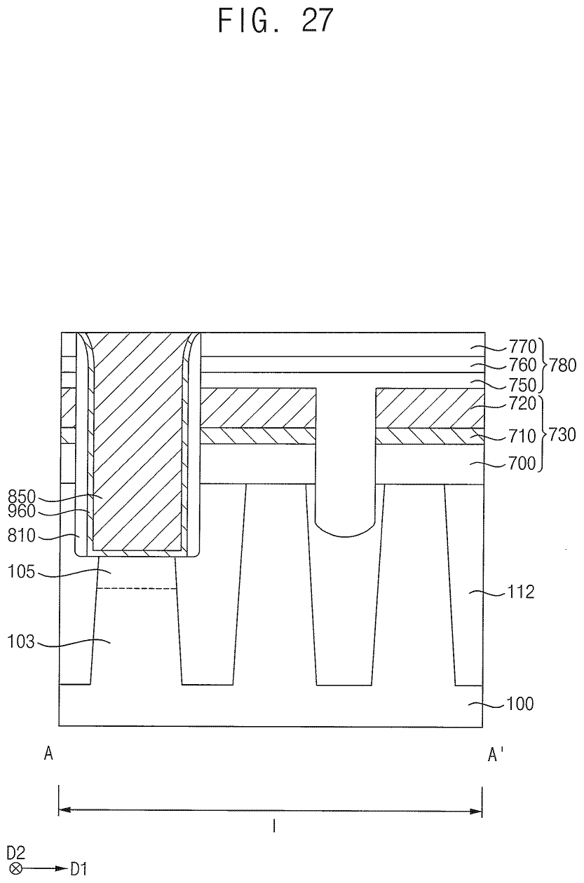

FIGS. 26 and 27 are cross-sectional views illustrating a method of manufacturing a semiconductor device of FIGS. 25A and 25B in accordance with an example embodiment. This method may include processes substantially the same as or similar to those illustrated with reference to FIGS. 3 to 24 and FIGS. 1 and 2, and thus repeated explanations thereof are omitted herein.

Referring to FIG. 26, processes substantially the same as or similar to those illustrated with reference to FIGS. 3 to 6 may be performed, and the insulation pad layer structure 780 may be formed on the conductive pad structure 730 to fill the first opening 740.

Without forming the first and second etch stop layers 790 and 800, the first mask may be formed on the insulation pad layer structure 780, and the insulation pad layer structure 780, the conductive pad structure 730, the active pattern 103, the isolation pattern 112 and the gate mask 160 of the gate structure 170 may be partially etched to form the second opening 805.

An ion implantation process may be performed on the exposed portion of the active pattern 103 by the second opening 805 to form the impurity region 105, the first mask may be removed, the first lower spacer layer may be formed on the bottom and the sidewall of the second opening 805 and the upper surface of the third insulation pad layer 770, and may be anisotropically etched to form the first lower spacer 810 on the sidewall of the second opening 805 so that the upper surface of the active pattern 103 may be exposed.

A preliminary second ohmic contact layer 950 may be formed on the bottom of the second opening 805, the sidewall and the upper surface of the first lower spacer 810, and the upper surface of the third insulation pad layer 770.

The preliminary second ohmic contact layer 950 may include, for example, polysilicon, and for example, a gas phase doping (GPD) process may be performed on the preliminary second ohmic contact layer 950 so that impurities may be doped thereinto. Thus, the preliminary second ohmic contact layer 950 may include polysilicon doped with n-type or p-type impurities.

Referring to FIG. 27, a fourth metal layer may be formed on the preliminary second ohmic contact layer 950, a heat treatment process may be performed on the fourth metal layer so that the fourth metal layer and the preliminary second ohmic contact layer 950 may be reacted with each other. Thus, the preliminary second ohmic contact layer 950 may be converted into a second ohmic contact layer 960.

The conductive filling layer may be formed on the second ohmic contact layer to fill the second opening 805, and an etch back process and/or a CMP process may be performed to form the conductive filling pattern 850 and a second ohmic contact pattern 960 covering a lower surface and a sidewall of the conductive filling pattern 850 in the second opening 805.

Referring to FIGS. 25A and 25B again, processes substantially the same as or similar to those illustrated with reference to FIGS. 14 to 24 and FIGS. 1 and 2 to complete the fabrication of the semiconductor device.

As illustrated above, the preliminary second ohmic contact layer 950 contacting the bottom and the sidewall of the second opening 805 having the bottom with an area greater than the area of the upper surface of the active pattern 103, and a silicidation process may be performed on the preliminary second ohmic contact layer 950 to form the second ohmic contact pattern 955. Thus, even if the upper surface of the active pattern 103 has a small area (e.g., when the upper surface of the active pattern 103 exposed by the second opening 805 has a small area as shown in FIG. 25B), the silicidation process may be performed on the preliminary second ohmic contact layer 950 having a relatively large area, so that the second ohmic contact pattern 960 having a relatively large area may be easily formed.

Unlike the method illustrated with reference to FIGS. 1 to 24, the first sacrificial layer 840 may not be formed in the second opening 805, and the upper portion of the fourth conductive pad 830 may not be removed by an etching process. Thus, the cleansing process may not be further performed.

In some example embodiments, the preliminary second ohmic contact layer 950 may be formed on the first lower spacer 810, and a silicidation process may be performed on the preliminary second ohmic contact layer 950 to form the second ohmic contact pattern 960. Thus, the second lower spacer 820 may not be formed in order to prevent the first lower spacer 810 from being damaged during the etching process and/or the cleansing process.

Accordingly, the lower spacer structure in the second opening 805 may include a single layer so as to have a relatively small thickness, and thus a space for forming the conductive filling pattern 850 may be easily acquired.

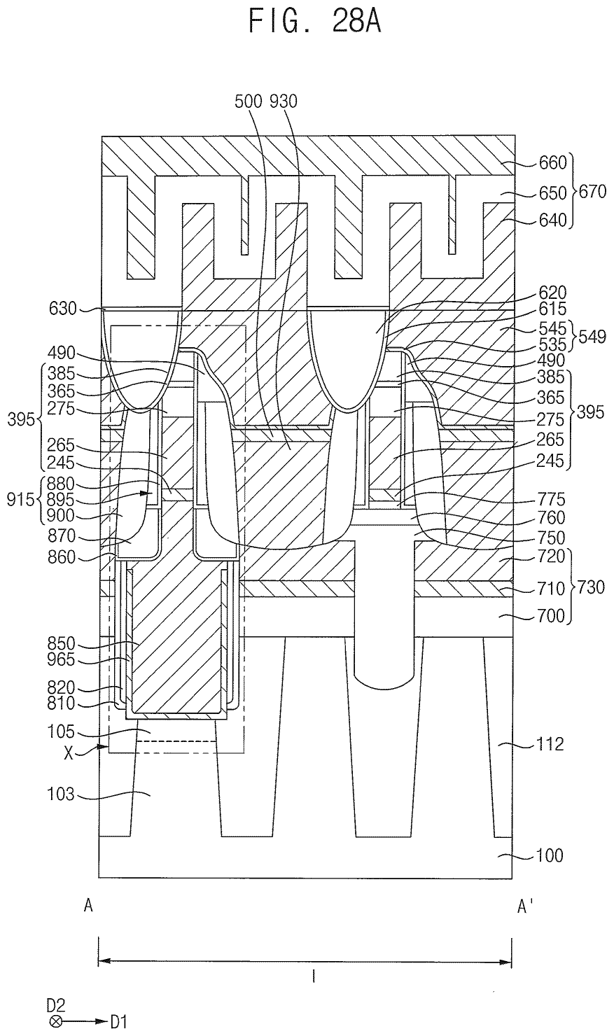

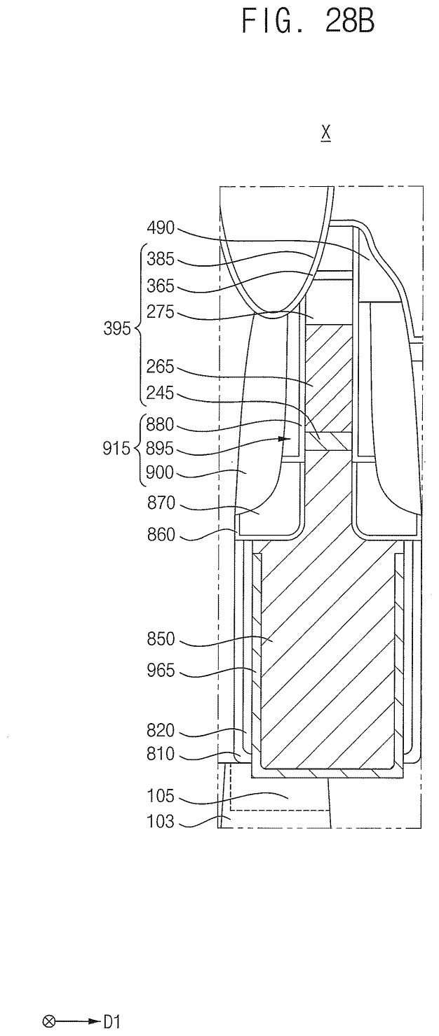

FIGS. 28A and 28B are cross-sectional views illustrating semiconductor devices in accordance with an example embodiment, which correspond to FIGS. 25A and 25B, respectively. FIG. 28B is an enlarged cross-sectional view of region X in FIG. 28A.

This semiconductor device may be substantially the same as or similar to that of FIGS. 25A and 25B, except for the filling structure.

Referring to FIGS. 28A and 28B, the filling structure may include the first contact plug structure and the lower spacer structure on the sidewall of the first contact plug structure, and the first contact plug structure may include a third ohmic contact pattern 965 on the upper surface of the active pattern 103 and the portion of the isolation pattern 112 adjacent thereto, and the conductive filling pattern 850.

In some example embodiments, the third ohmic contact pattern 965 may cover a lower surface and a sidewall of a portion of the lower portion of the conductive filling pattern 850.

The lower spacer structure may include the first and second lower spacers 810 and 820, and may contact an outer sidewall of the third ohmic contact pattern 965 and a lower portion of a sidewall of the conductive filling pattern 850.

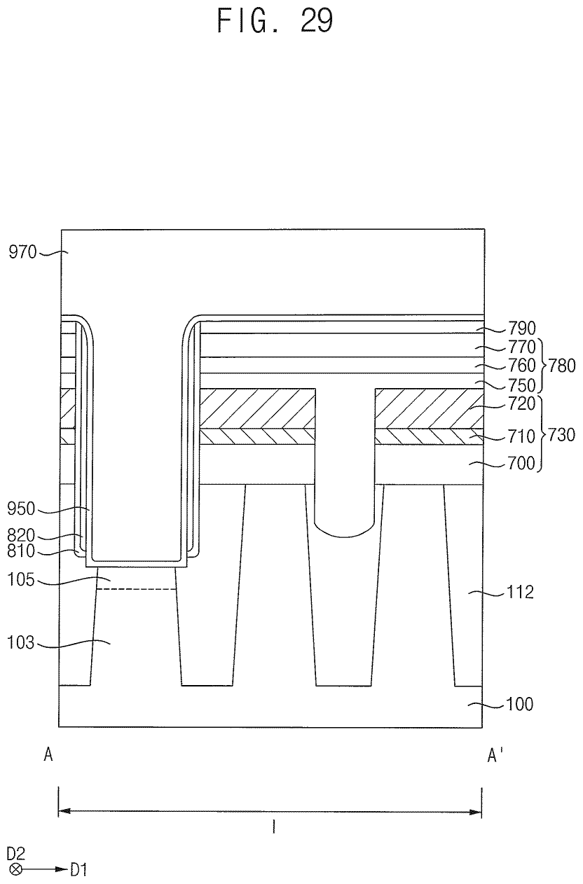

FIGS. 29 to 31 are cross-sectional views illustrating a method of manufacturing a semiconductor device of FIGS. 28A and 28B in accordance with an example embodiment. This method may include processes substantially the same as or similar to those illustrated with reference to FIGS. 1 to 24, or processes substantially the same as or similar to those illustrated with reference to FIGS. 24 to 27, and thus repeated explanations thereof are omitted herein.

Referring to FIG. 29, processes substantially the same as or similar to those illustrated with reference to FIGS. 1 to 9 may be performed to form the lower spacer structure including the first and second lower spacers 810 and 820 on the sidewall of the second opening 805.

However, the first and second etch stop layers 790 and 800 may not be formed on the insulation pad layer structure 780.

The preliminary second ohmic contact layer 950 including polysilicon doped with n-type or p-type impurities may be formed on the bottom of the second opening 805, the sidewall and the upper surface of the second lower spacer 820, the upper surface of the first lower spacer 810 and the upper surface of the third insulation pad layer 770.

A fourth sacrificial layer 970 may be formed on the preliminary second ohmic contact layer 950. The fourth sacrificial layer 970 may include, for example, spin-on-hardmask (SOH) or amorphous carbon layer (ACL).

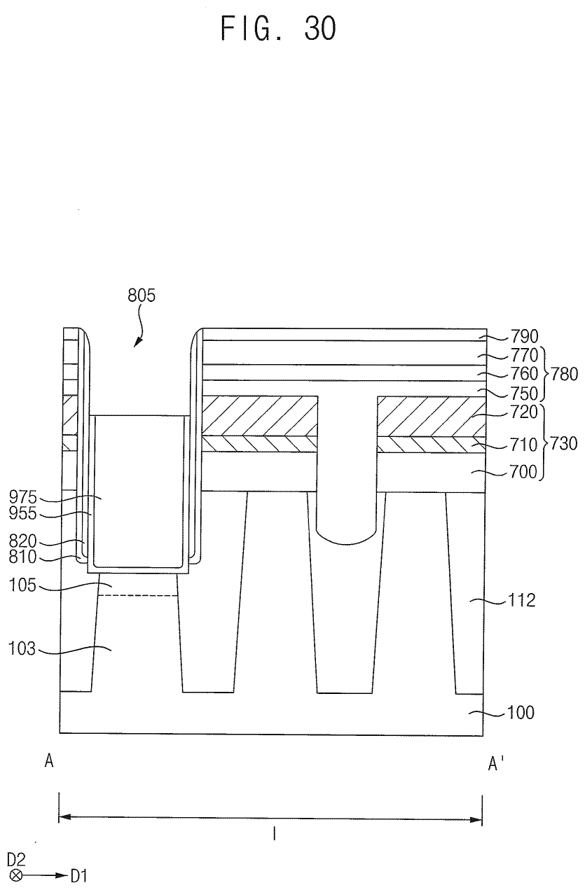

Referring to FIG. 30, an upper portion of the fourth sacrificial layer 970 may be removed by, for example, an etch back process to form a fourth sacrificial pattern 965 so that an upper portion of the preliminary second ohmic contact layer 950 may be exposed.

The exposed upper portion of the preliminary second ohmic contact layer 950 may be removed to form a preliminary third ohmic contact pattern 955.

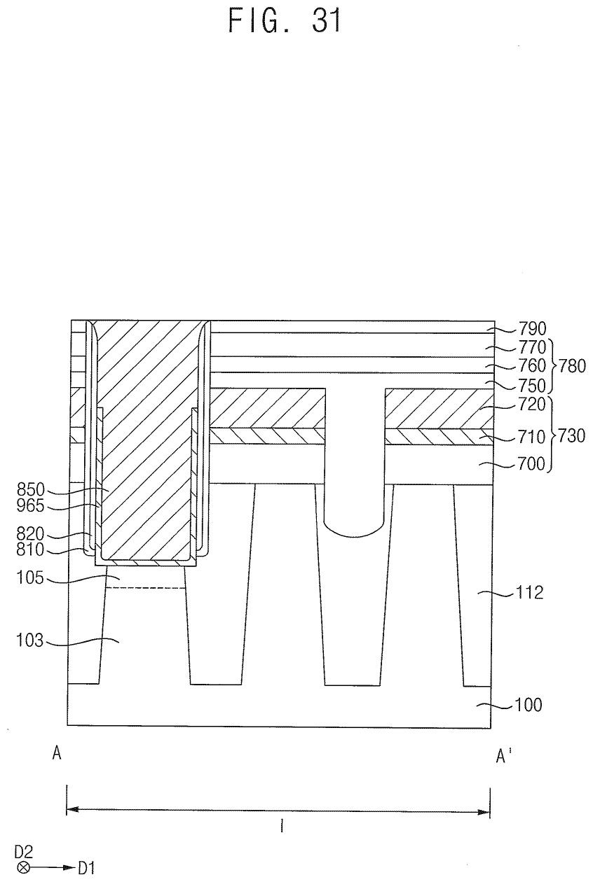

Referring to FIG. 31, the fourth sacrificial pattern 965 may be removed by, for example, an ashing process and/or stripping process, and a silicidation process may be performed so that the preliminary third ohmic contact pattern 955 may be converted into a third ohmic contact pattern 965.

The conductive filling pattern 850 may be formed on the third ohmic contact pattern 965 and the second lower spacer 820 to fill the second opening 805.

Referring to FIG. 28 again, processes substantially the same as or similar to those illustrated with reference to FIGS. 14 to 24 and FIGS. 1 and 2 may be performed to complete the fabrication of the semiconductor device.

As illustrated above, the preliminary second ohmic contact layer 950 contacting the upper surface of the active pattern 103 may be formed on the bottom and the sidewall of the second opening 805, and the bottom of the preliminary second ohmic contact layer 950 may have an area greater than the area of the active pattern 103, the upper portion of the preliminary second ohmic contact layer 950 may be removed using the fourth sacrificial pattern 965 to form the preliminary third ohmic contact pattern 955, and a silicidation process may be performed to form the third ohmic contact pattern 965. Thus, even if the upper surface of the active pattern 103 has a small area (when the upper surface of the active pattern 103 exposed by the second opening 805 has a small area due to the misalignment as shown in FIG. 28B), the silicidation process may be performed on the preliminary third ohmic contact pattern 955 having a relatively large area, so that the third ohmic contact pattern 965 having a relatively large area may be easily formed.

Unlike the method illustrated with reference to FIGS. 25 to 27, instead of performing the silicidation process on an entire portion of the preliminary second ohmic contact layer 950 in the second opening 805 to form the second ohmic contact pattern 960 on the entire portion of the sidewall of the second opening 805, the silicidation process may be performed on only the preliminary third ohmic contact pattern 955, which may be formed by removing the upper portion of the preliminary second ohmic contact layer 950 in the second opening 805, to form the third ohmic contact pattern 965 on the lower sidewall of the second opening 805.

Thus, a space for forming the conductive filling pattern 850 in the second opening 805 may be easily acquired.

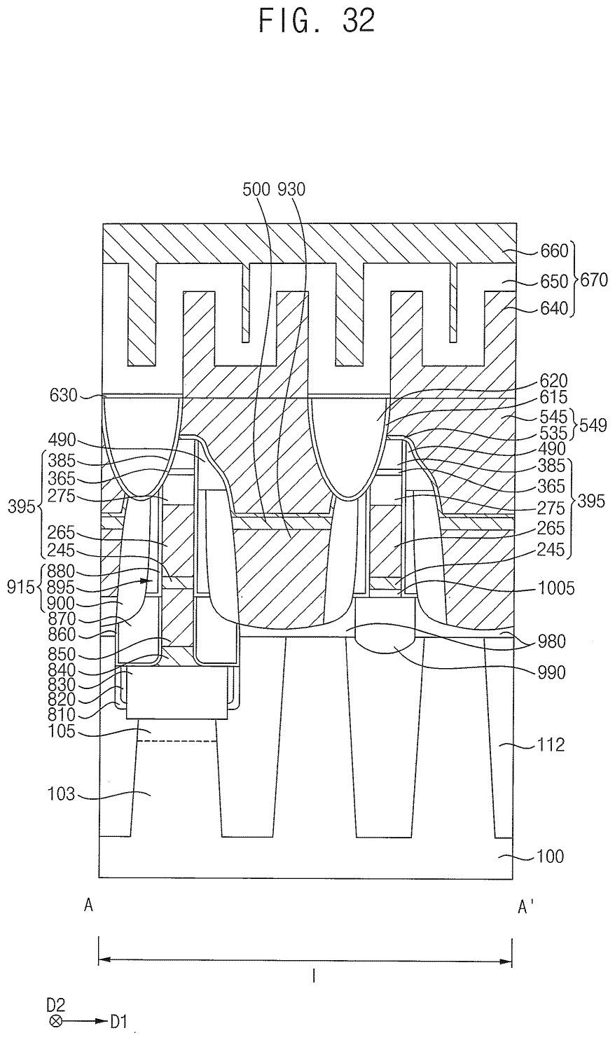

FIG. 32 is a cross-sectional view illustrating a semiconductor device in accordance with an example embodiment, which corresponds to FIG. 2A.

This semiconductor device may be substantially the same as or similar to that of FIGS. 1 and 2, except for some elements. Thus, repeated explanations are omitted herein.

Referring to FIG. 32, a fifth conductive pad 980 and a fourth insulation pad 990 may be formed on the active pattern 103, the isolation pattern 112 and the gate structure 170.

In some example embodiments, a plurality of fifth conductive pads 980 may be spaced apart from each other in the first and second directions D1 and D2, and may be arranged in a lattice pattern in a plan view. The fourth insulation pad 990 may include a first extension portion extending in the first direction D1 and a second extension portion extending in the second direction D2, which may be connected with each other. Thus, each of the fifth conductive pads 980 may be surrounded by the fourth insulation pad 990.

In some example embodiments, the fifth conductive pad 980 may overlap in the vertical direction an end portion of the active pattern 103 extending in the third direction D3 and a portion of the isolation pattern 112 adjacent thereto in the first direction D1.

The fifth conductive pad 980 may include a conductive material (e.g., doped polysilicon), a metal (e.g., tungsten or ruthenium), a metal nitride (e.g., titanium nitride or tantalum nitride), or graphene. In an example embodiment, the fifth conductive pad 980 may include a single layer including one of the above conductive materials. In some example embodiments, the fifth conductive pad 980 may have a multi-layered structure including stacked layers containing the above conductive materials, respectively. FIG. 32 shows that the fifth conductive pad 980 includes a single layer.

The fourth pad 990 may include an insulating nitride(e.g., silicon nitride).

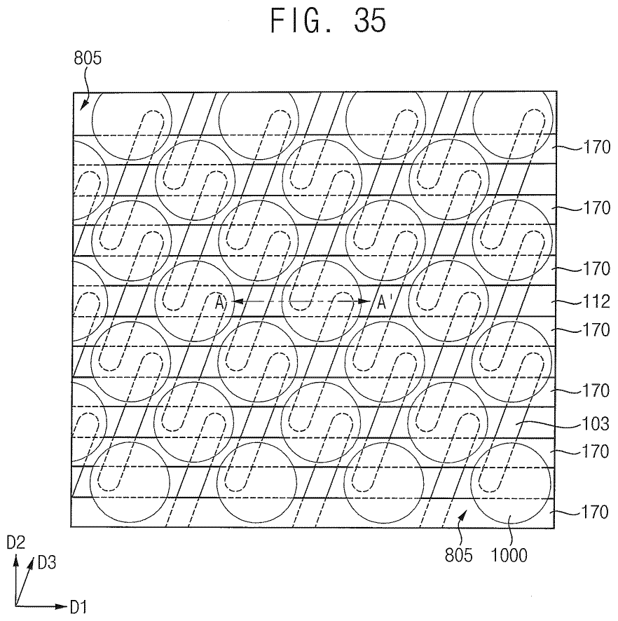

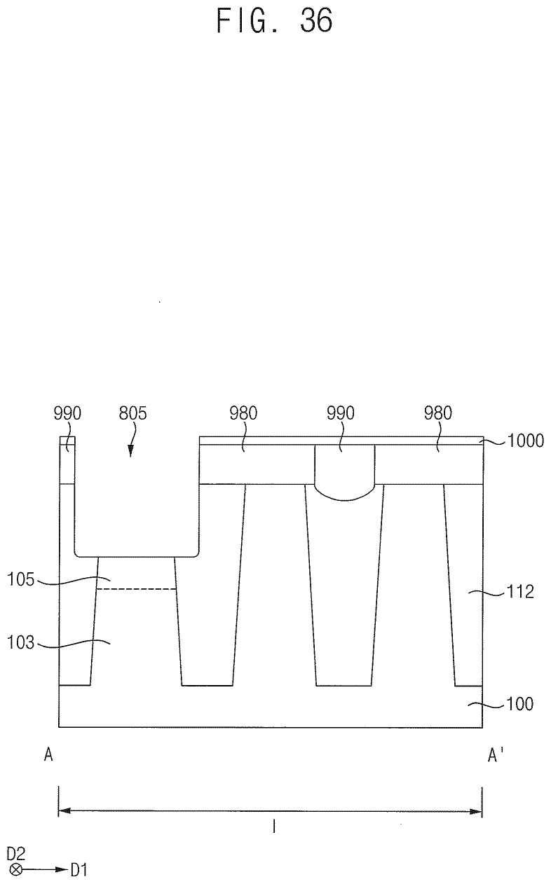

The filling structure may be formed in the second opening 805 (refer to FIGS. 35 and 36) extending through the fifth conductive pad 980, the fourth insulation pad 990, an upper portion of the active pattern 103, and upper portion of the isolation pattern 112 and an upper portion of the gate structure 170, and may include the first contact plug structure, the lower spacer structure, the second capping pattern 860 and the insulating filling pattern 870, as the filling structure shown in FIGS. 1 and 2.

However, unlike that of FIGS. 1 and 2, the conductive filling pattern 850 included in the first contact plug structure may have a constant width along the vertical direction, instead of the lower and upper portions having the different widths, and the first ohmic contact pattern 840 may have a width substantially the same as that of the conductive filling pattern 850.

The lower spacer structure including the first and second lower spacers 810 and 820 may cover the sidewall of the fourth conductive pad 830, and upper surfaces of the first and second lower spacers 810 and 820 may be substantially coplanar with the upper surface of the fourth conductive pad 830.

Thus, the second capping pattern 860 may cover the upper surfaces of the fourth conductive pad 830 and the first and second lower spacers 810 and 820. The second capping pattern 860 may be on sidewalls of the ohmic contact pattern 840 and the conductive filling pattern 850 and an upper surface of the lower spacer structure 810 and 820.

The bit line structure 395 may be formed on the filling structure, and a fifth insulation pad 1005 may be formed between a portion of the bit line structure 395 at an outside of the second opening 805 and the fourth insulation pad 990. The fifth insulation pad 1005 may include an insulating nitride (e.g., silicon nitride).

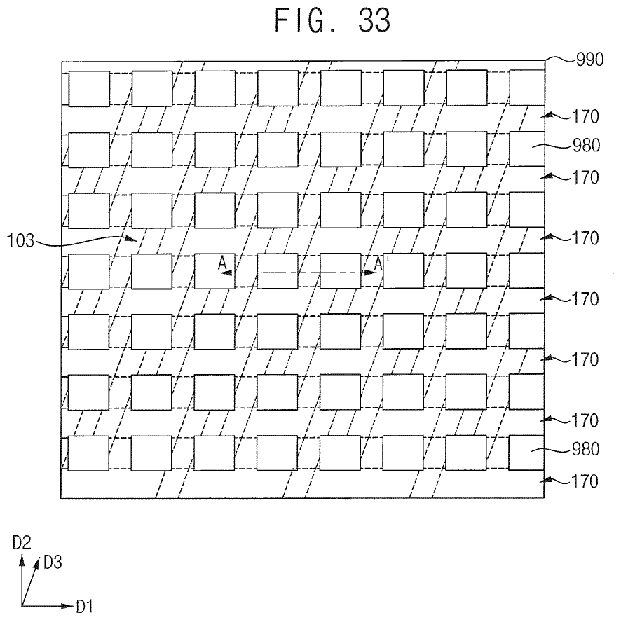

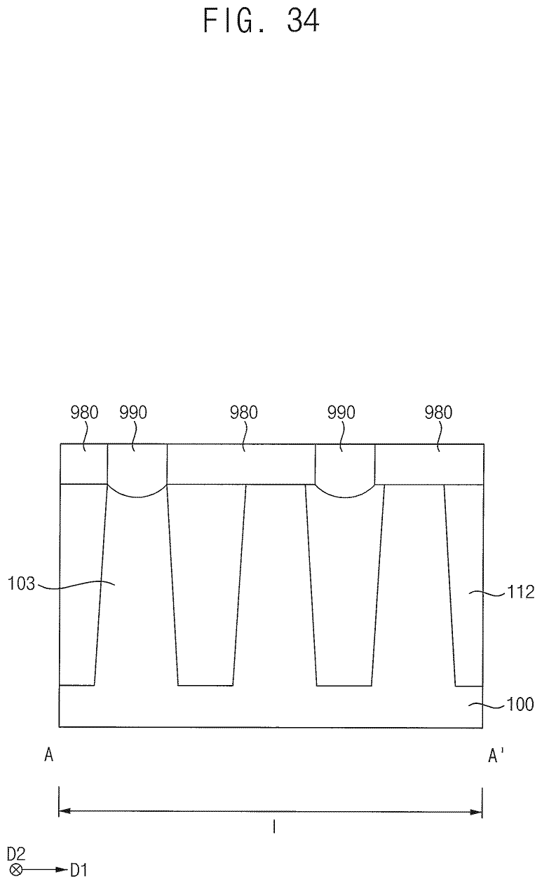

FIGS. 33 to 37 are cross-sectional views illustrating a method of manufacturing a semiconductor device of FIG. 32 in accordance with an example embodiment. This method may include processes substantially the same as or similar to those illustrated with reference to FIGS. 1 to 24, and thus repeated explanations thereof are omitted herein.

Referring to FIGS. 3 and 4, processes substantially the same as or similar to those illustrated with reference to FIGS. 3 and 4 may be performed, and a fifth conductive pad 980 and a fourth insulation pad 990 may be formed on the substrate 100 having the active pattern 103, the isolation pattern 112 and the gate structure 170 thereon.

In some example embodiments, a fourth conductive pad layer may be formed on the substrate 100, the fifth conductive pad layer may be patterned to form a ninth opening partially exposing upper surfaces of the active pattern 103, the isolation pattern 112 and the gate structure 170 and a fifth conductive pad 980, and a fourth insulation pad 990 may be formed to fill the ninth opening. In some example embodiments, the fourth insulation pad layer may be formed on the substrate 100, the fourth insulation pad layer may be patterned to form the fourth insulation pad 990, and the fifth conductive pad 980 may be formed.

In some example embodiments, the ninth opening may include a first portion extending in the first direction D1 and a second portion extending in the second direction D2, which may be connected with each other. Thus, the fourth insulation pad 990 in the ninth opening may have a first extension portion extending in the first direction D1 and a second extension portion extending in the second direction D2, which may be connected with each other. In some example embodiments, a plurality of fifth conductive pads 980 may be spaced apart from each other in the first and second directions D1 and D2, and may be arranged in a lattice pattern in a plan view.

In some example embodiments, the fifth conductive pad 980 may overlap in the vertical direction an end portion of the active pattern 103 extending in the third direction D3 and a portion of the isolation pattern 112 adjacent thereto in the first direction D1.

Referring to FIGS. 35 and 36, a fifth insulation pad layer may be formed on the fifth conductive pad 980 and the fourth insulation pad 990, and may be patterned to form a fifth insulation pad layer 1000.

Processes substantially the same as or similar to those illustrated with reference to FIGS. 7 and 8 may be performed.

Thus, the fifth conductive pad 980, the fourth insulation pad 990, the active pattern 103, the isolation pattern 112 and the gate mask 160 of the gate structure 170 may be partially etched using the fifth insulation pad layer 100 as an etching mask to form the second opening 805.

In some example embodiments, the fifth insulation pad layer 1000 may have a shape of a circle or an ellipse in a plan view, and a plurality of fifth insulation pad layers 1000 may be spaced apart from each other in the first and second directions D1 and D2. Each of the fifth insulation pad layers 1000 may overlap in the vertical direction end portions of neighboring ones of the active patterns 103, respectively, in the first direction D1 and a portion of the isolation pattern 112 therebetween.

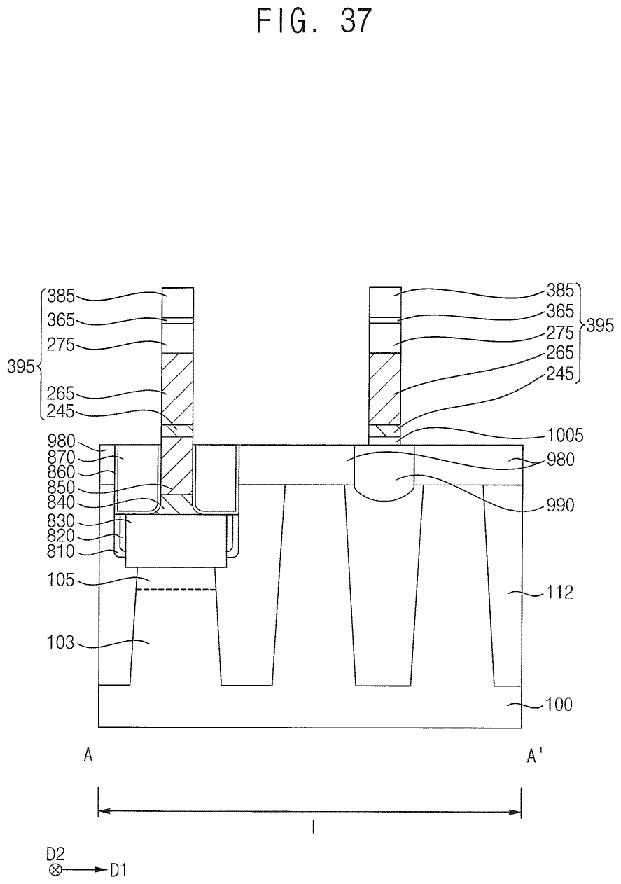

Referring to FIG. 37, processes substantially the same as or similar to those illustrated with reference to FIGS. 9 to 16 may be performed.

Thus, the impurity region 105 may be formed at an upper portion of the active pattern 103 exposed by the second opening 805, and the filling structure including the first contact plug structure, the lower spacer structure, the second capping pattern 860 and the insulating filling pattern 870 may be formed in the second opening 805.

The bit line structure 395 may be formed on the filling structure, and a fifth insulation pad 1005 may be formed between a portion of the bit line structure 395 at an outside of the second opening 805 and the fourth insulation pad 990.

Referring to FIG. 32 again, processes substantially the same as or similar to those illustrated with reference to FIGS. 17 to 24 and FIGS. 1 and 2 may be performed to complete the fabrication of the semiconductor device.

The second contact plug 930 may contact the fifth conductive pad 980.

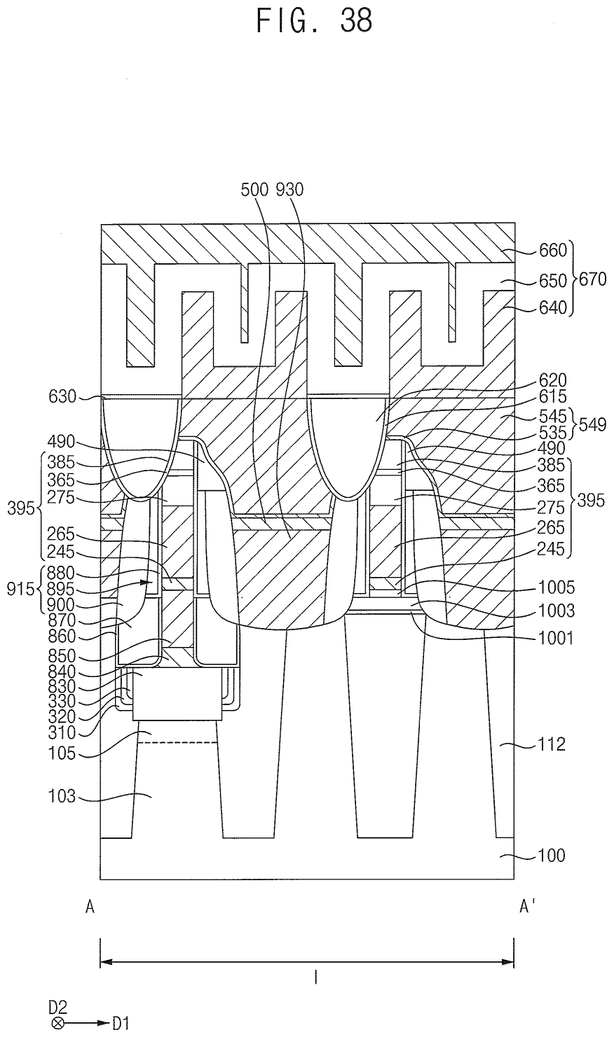

FIGS. 38 to 40 are cross-sectional views illustrating semiconductor devices, respectively, in accordance with some example embodiments, which correspond to FIG. 2A.

These semiconductor devices may be substantially the same as or similar to that of FIGS. 1 and 2, except for some elements. Thus, repeated explanations are omitted herein.

Referring to FIG. 38, the lower spacer structure included in the semiconductor device may include third, fourth and fifth lower spacers 310, 320 and 330 sequentially stacked from the sidewall of the second opening 805, instead of the first and second lower spacers 810 and 820, and thus the third to fifth lower spacers 310, 320 and 330 sequentially stacked in the horizontal direction may be formed on the sidewall of the fourth conductive pad 830.

In some example embodiments, the third to fifth lower spacers 310, 320 and 330 may include, for example, silicon nitride, silicon oxide and silicon nitride, respectively.

In some example embodiments, the fourth lower spacer 320 may include an air, and thus may be an air spacer.

The semiconductor device may not include the conductive pad structure 730, or the fifth conductive pad 980 and the fourth insulation pad 990, and thus the second contact plug 930 included in the second contact plug structure may directly contact the active pattern 103 to be electrically connected thereto.

Additionally, sixth and seventh insulation pads 1001 and 1003 may be stacked between the fifth insulation pad 1005 under the portion of the bit line structure 395 at the outside of the second opening 805 and the isolation pattern 112 or the active pattern 103. The sixth and seventh insulation pads 1001 and 1003 may include silicon nitride and silicon oxide, respectively.

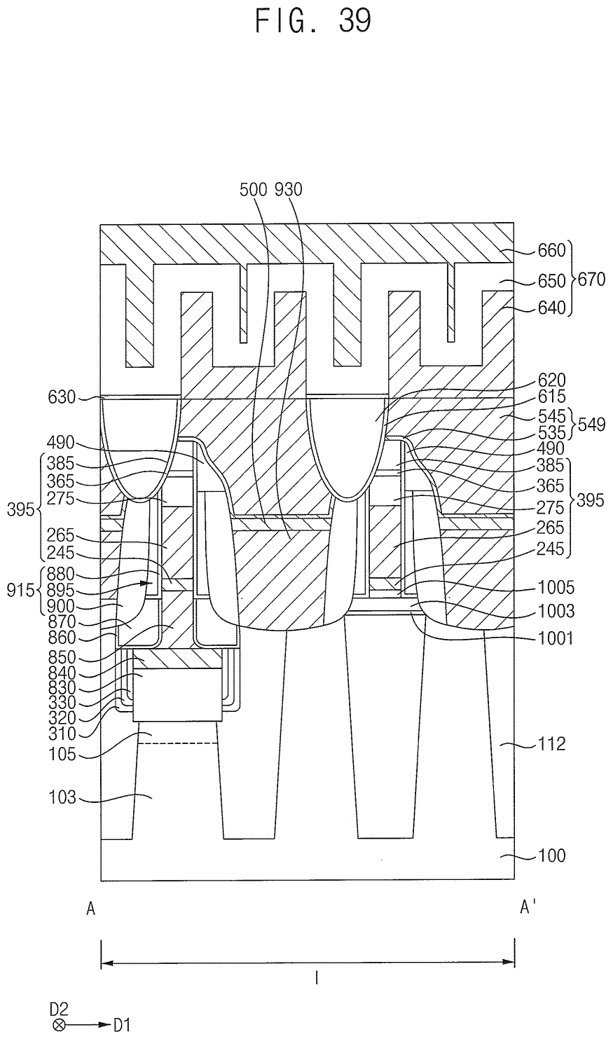

Referring to FIG. 39, the lower spacer structure may cover not only the sidewall of the fourth conductive pad 830 but also the sidewall of the first ohmic contact pattern 840, and thus the second capping pattern 860 may cover the upper surface of the first ohmic contact pattern 840 and the upper surface of the lower spacer structure.

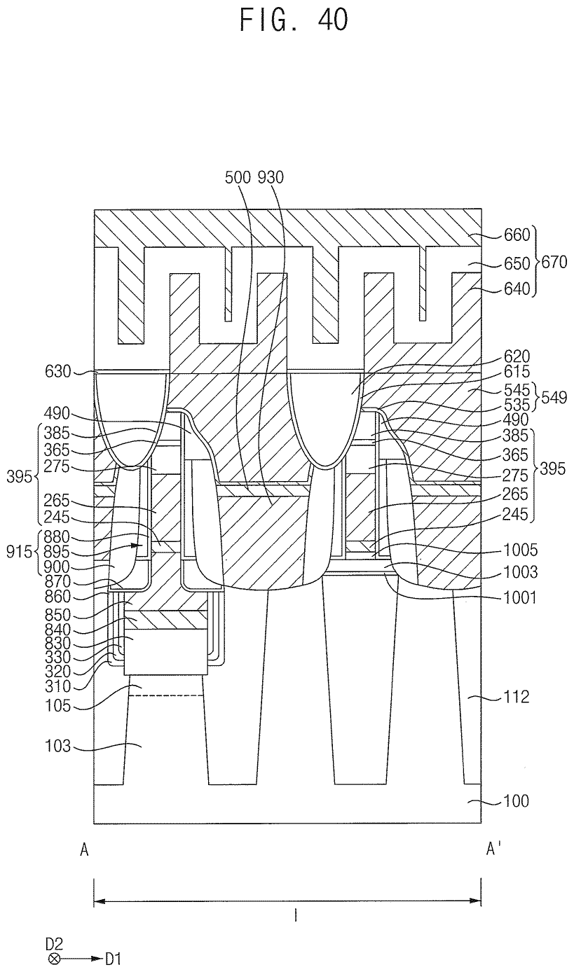

Referring to FIG. 40, the lower spacer structure may cover not only the sidewalls of the fourth conductive pad 830 and the first ohmic contact pattern 840 but also the sidewall of the lower portion of the conductive filling pattern 850, and thus the second capping pattern 860 may cover the sidewall of the upper portion of the conductive filling pattern 850, the upper surface of the lower portion of the conductive filling pattern 850 and the upper surface of the lower spacer structure.

It should be understood that some example embodiments described herein should be considered in a descriptive sense only and not for purposes of limitation. While some example embodiments have been particularly shown and described, it will be understood by one of ordinary skill in the art that variations in form and detail may be made therein without departing from the spirit and scope of the claims.

What is claimed is:

1. A semiconductor device comprising:
a first contact plug structure on a substrate;
a lower spacer structure on a sidewall of the first contact plug structure; and
a bit line structure on the first contact plug structure, the bit line structure including a conductive structure and an insulation structure stacked in a vertical direction substantially perpendicular to an upper surface of the substrate,
wherein the first contact plug structure includes,
a conductive pad contacting the upper surface of the substrate,
an ohmic contact pattern on the conductive pad, and
a conductive filling pattern on the ohmic contact pattern, the conductive filling pattern including metal, and including a lower portion having a relatively large width and an upper portion having a relatively small width, and
wherein the lower spacer structure contacts a sidewall of the conductive filling pattern.

2. The semiconductor device according to claim 1, wherein the conductive pad includes doped single crystalline silicon or doped polysilicon, and the ohmic contact pattern includes metal silicide.

3. The semiconductor device according to claim 1, wherein
an active pattern is on the substrate, and the conductive pad contacts an upper surface of the active pattern, and
an area of an upper surface of the conductive pad is greater than an area of the upper surface of the active pattern.

4. The semiconductor device according to claim 3, wherein an area of a lower surface of the conductive pad is greater than an area of the upper surface of the active pattern.

5. The semiconductor device according to claim 3, wherein the active pattern includes an impurity region at an upper portion thereof, the impurity region contacting a lower surface of the conductive pad.

6. The semiconductor device according to claim 1, wherein the lower spacer structure includes:
a second lower spacer contacting the sidewall of the first contact plug structure and including silicon oxycarbide; and
a first lower spacer contacting an outer sidewall of the second lower spacer and including silicon oxide.

7. The semiconductor device according to claim 1, wherein the lower spacer structure contacts sidewalls of the conductive pad, the ohmic contact pattern and the conductive filling pattern.

8. The semiconductor device according to claim 7, further comprising:
a capping pattern covering a sidewall of the upper portion of the conductive filling pattern, an upper surface of the lower portion of the conductive filling pattern, and an upper surface of the lower spacer structure, a width of the upper portion of the conductive filling pattern being narrow than a width of the lower portion of the conductive filling pattern; and
an insulating filling pattern on the capping pattern.

9. The semiconductor device according to claim 8, further comprising:
an upper spacer structure on the capping pattern and the insulating filling pattern, the upper spacer structure covering a sidewall of the bit line structure.

10. The semiconductor device according to claim 1, further comprising:
an active pattern and an isolation pattern on the substrate, the isolation pattern covering a sidewall of the active pattern,
wherein the first contact plug structure contacts an upper surface of a central portion of the active pattern.

11. The semiconductor device according to claim 10, further comprising:
a conductive pad structure on the active pattern and the isolation pattern, the conductive pad structure overlapping at least a portion of the first contact plug structure in a horizontal direction substantially parallel to the upper surface of the substrate.

12. The semiconductor device according to claim 11, wherein
the conductive pad structure contacts each of opposite edge portions of the active pattern, and
the semiconductor device further comprises,
a second contact plug structure on the conductive pad structure, and
a capacitor on the first contact plug structure.

13. A semiconductor device comprising:
a contact plug structure on a substrate;
a lower spacer structure on a sidewall of the contact plug structure; and
a bit line structure on the contact plug structure, the bit line structure including a conductive structure and an insulation structure stacked in a vertical direction substantially perpendicular to an upper surface of the substrate,
wherein the contact plug structure includes,
an ohmic contact pattern contacting the upper surface of the substrate, and
a conductive filling pattern on the ohmic contact pattern, the conductive filling pattern including metal, the conductive filling pattern including a lower portion having a relatively large width and an upper portion having a relatively small width, and
wherein the ohmic contact pattern covers at least a portion of a sidewall of the lower portion of the conductive filling pattern.

14. The semiconductor device according to claim 13, wherein the ohmic contact pattern includes metal silicide.

15. The semiconductor device according to claim 13, wherein
the ohmic contact pattern covers an entire portion of the sidewall of the lower portion of the conductive filling pattern, and
wherein the lower spacer structure includes silicon oxide.

16. The semiconductor device according to claim 13, wherein
the ohmic contact pattern covers only a portion of the sidewall of the conductive filling pattern, and
the lower spacer structure includes,
a second lower spacer contacting an outer sidewall of the ohmic contact pattern and another portion of the sidewall of the conductive filling pattern, the second lower spacer including silicon oxycarbide (SiOC), and
a first lower spacer contacting an outer sidewall of the second lower spacer, the first lower spacer including silicon oxide.

17. The semiconductor device according to claim 13, wherein
an active pattern is on the substrate, and
the active pattern includes an impurity region at an upper portion thereof, the impurity region contacting a lower surface of the ohmic contact pattern.

18. A semiconductor device comprising:
an active pattern on a substrate;
a contact plug structure on the active pattern, the contact plug structure including,
a conductive pad on an upper surface of the active pattern,
an ohmic contact pattern on the conductive pad, and
a conductive filling pattern on the ohmic contact pattern,
a lower spacer structure on a sidewall of the conductive pad;
a capping pattern on sidewalls of the ohmic contact pattern and the conductive filling pattern and an upper surface of the lower spacer structure;
an insulating filling pattern on the capping pattern; and
a bit line structure on the contact plug structure, the bit line structure including a conductive structure and an insulation structure stacked in a vertical direction substantially perpendicular to an upper surface of the substrate.

19. The semiconductor device according to claim 18, wherein the lower spacer structure includes:
a first lower spacer contacting the sidewall of the conductive pad and including silicon nitride;
a second lower spacer contacting an outer sidewall of the first lower spacer and including silicon oxide; and
a third lower spacer contacting an outer sidewall of the second lower spacer and including silicon nitride.

20. The semiconductor device according to claim 18, wherein the conductive pad includes polysilicon doped with impurities, the ohmic contact pattern includes metal silicide, the conductive filling pattern includes metal, the capping pattern includes silicon oxide, and the insulating filling pattern includes silicon nitride.
